(19) United States
(12) Patent Application Publication
(10) Pub. No.: US 2014/0190562 A1
(43) Pub. Date: Jul. 10, 2014

(54) SOLAR CELL BACKSHEET AND SOLAR CELL MODULE

(71) Applicant: FUJIFILM Corporation, Tokyo (JP)

(72) Inventors: Yuuki TESHIMA, Kanagawa (JP); Mitsunori HACHISUKA, Kanagawa (JP); Naoya IMAMURA, Kanagawa (JP)

(73) Assignee: FUJIFILM Corporation, Tokyo (JP)

(21) Appl. No.: 14/204,061

(22) Filed: Mar. 11, 2014

Related U.S. Application Data
(63) Continuation of application No. PCT/JP2012/072788, filed on Sep. 6, 2012.

(30) Foreign Application Priority Data
Sep. 14, 2011 (JP) 2011-200955

(51) Int. Cl. H01L 31/048

(52) U.S. Cl. CPC H01L 31/0487
USPC 136/256

(57) ABSTRACT

A solar cell backsheet is provided which includes: a substrate that is a biaxially stretched polyethylene terephthalate film having a pre-peak temperature of from 160° C. to 225° C. as measured by differential scanning calorimetry (DSC); a coating layer that is provided at at least one side of the substrate, and includes a binder containing an acrylic resin, a crosslinked structure part derived from a carbodiimide crosslinking agent, and inorganic fine particles; and an adhesive layer that is provided on the coating layer, and includes a resin binder as a main component.

### CROSS-REFERENCE TO RELATED APPLICATIONS

This application is a continuation application of International Application No. PCT/JP2012/072788, filed Sep. 6, 2012, the disclosure of which is incorporated herein by reference in its entirety. Further, this application claims priority from Japanese Patent Application No. 2011-200955, filed Sep. 14, 2011, the disclosure of which is incorporated herein by reference in its entirety.

### TECHNICAL FIELD

The present invention relates to a solar cell backsheet and a solar cell module.

### BACKGROUND ART

Polyester is used for various applications such as electrical insulation uses and optical uses. In recent years, among the electrical insulation uses, solar cell uses such as a backside protective sheet (so-called backsheet) for solar cells have been receiving attention.

On the other hand, polyester usually has many carboxy and hydroxyl groups on its surface, and tends to cause hydrolysis reaction in a humid environment, which results in deterioration over time. For example, solar cell modules are usually used in outdoor environments which are always exposed to wind and weather, and subjected to conditions which promote hydrolysis reaction. Therefore, when polyester is used in a solar cell, inhibition of hydrolyzability of polyester is an important property.

Common solar cell elements are covered with a sealing material made of an ethylene-vinyl acetate copolymer (EVA) resin. In order to protect a solar cell, it is important that the backsheet is bonded to the sealing material, so as to support the sealing material containing the solar cell element. Accordingly, the adhesion between the backsheet and the sealing material is preferably high.

For example, the adhesion between them can be temporarily increased by subjecting the surface of the backsheet to corona treatment or flame treatment, but changes over time after the surface treatment can result in decrease of the adhesion, or blocking of the surface-treated backsheet.

Therefore, a functional layer, or a so-called adhesive layer that provides adhesion to the sealing material may be formed on the backsheet. In this case, the backsheet having the adhesive layer is required to function as an adhesive layer, while functioning as a backsheet.

As a technique related to the above-described circumstances, for example, an easy adhesion polyester film for a solar cell backside protective film is disclosed which is composed of a polyester film and a resin film formed thereon, in which the resin film is formed by applying a coating liquid to the film, and the coating liquid contains from 10 to 100% by weight of a crosslinking agent (A) with respect to 100% by weight of solid content, for the purpose of obtaining an easy adhesion polyester film for a solar cell backside protective film which has marked mechanical properties, heat resistance, and moisture resistance, and gives favorable adhesion to EVA that is a sealing material (for example, refer to Japanese Patent Application Laid-Open (JP-A) No. 2006-152013).

In addition, a solar cell backsheet film is disclosed which includes: a white layer composed of a coating film of a white layer-forming aqueous composition containing a white pigment, an aqueous binder, and an inorganic oxide filler; and an adhesion protective layer made of a coating film of an adhesion protective layer-forming aqueous composition containing an aqueous binder, on at least one side of a substrate film, for the purpose of obtaining a solar cell backsheet film which provides favorable production efficiency, contains a white pigment uniformly dispersed in the layer, and gives favorable adhesion between the layers (for example, refer to JP-A No. 2011-146659).

In addition, for example, WO 2010/110119 discloses a polyester film for a solar cell having a carboxyl end group concentration of 13 eq/ton or less, and a minute endothermic peak temperature Tmeta (° C.) of 220° C. or lower as measured by differential scanning calorimetry (DSC), for the purpose of obtaining a polyester film for a solar cell having high heat resistance and hydrolysis resistance.

### SUMMARY OF INVENTION

### Technical Problem

However, even if the films described in JP-A No. 2006-152013, 2011-146659, or WO 2010/110119 give favorable adhesion to the sealing material, there has still been room for improvement in the adhesion between the adhesive layer and the substrate thereof. Therefore, there has also still been room for improvement in sufficiently supporting the sealing material containing a solar cell element, and thus, there has been a challenge in sufficiently developing the original function of a backsheet to protect a solar cell.

The invention has been made in view of the above-described circumstances, and it is an object to provide a solar cell backsheet which has excellent weather resistance and gives excellent adhesion between the adhesive layer and the substrate thereof, and a solar cell module with which stable electric generating performance can be provided over a long time.

### Solution to Problem

The invention includes the following embodiments.

<1> A solar cell backsheet including: a substrate that is a biaxially stretched polyethylene terephthalate film having a pre-peak temperature of from 160° C. to 225° C. as measured by differential scanning calorimetry (DSC); a coating layer that is provided at at least one side of the substrate, and includes a binder containing an acrylic resin, a crosslinked structure part derived from a carbodiimide crosslinking agent, and inorganic fine particles; and an adhesive layer that is provided on the coating layer, and includes a resin binder as a main component.

<2> The solar cell backsheet according to <1> described above, wherein an acid value A of the acrylic resin, an equivalent B of the carbodiimide crosslinking agent, and a mass ratio X of the carbodiimide crosslinking agent to the acrylic resin (carbodiimide crosslinking agent/acrylic resin) satisfies the following Formula (1).

(0.8AB)/56100<X<(2.0AB)/56100 (1)

<3> The solar cell backsheet according to <1> or <2> described above, wherein the inorganic fine particles contain tin oxide.

<4> The solar cell backsheet according to <1> or <2> described above, wherein the inorganic fine particles contain tin oxide as a main component, and a content of the inorganic fine particles in the coating layer is from 50% by mass to 500% by mass with respect to the total mass of the binder.

<5> The solar cell backsheet according to any one of <1> to <4> described above, wherein the pre-peak temperature of the substrate is from 205° C. to 225° C.

<6> The solar cell backsheet according to any one of <1> to <5> described above, wherein a content of the binder in the coating layer is from 0.02 g/m² to 0.1 g/m².

<7> The solar cell backsheet according to any one of <1> to <5> described above, wherein an equivalent B of the carbodiimide crosslinking agent is from 200 to 500.

<8> The solar cell backsheet according to any one of <1> to <7> described above, wherein the adhesive layer further contains a crosslinked structure part derived from an epoxy crosslinking agent.

<9> A solar cell module including: a transparent substrate into which sunlight enters, a solar cell element disposed at one side of the substrate, and the solar cell backsheet according to any one of <1> to <8> described above disposed at an opposite side of the solar cell element from a side of the solar cell element at which the substrate is disposed.

### Advantageous Effect of Invention

According to the invention, a solar cell backsheet is provided, which has excellent weather resistance and gives excellent adhesion between an adhesive layer and a substrate thereof.

In addition, according to the invention, a solar cell module with which stable electric generating performance can be provided over a long time is provided.

### BRIEF DESCRIPTION OF DRAWINGS

FIG. 1 is a top view of an example of a biaxial stretching machine.

### DESCRIPTION OF EMBODIMENTS

The solar cell backsheet of the invention is explained below in detail, and based on the explanation, the solar cell module of the invention is also described.

<Solar Cell Backsheet>

The solar cell backsheet of the invention includes: a substrate that is a biaxially stretched polyethylene terephthalate film having a pre-peak temperature of from 160° C. to 225° C. as measured by differential scanning calorimetry (DSC); a coating layer that is provided at at least one side of the substrate and includes a binder containing an acrylic resin, a crosslinked structure part derived from a carbodiimide crosslinking agent, and inorganic fine particles; and an adhesive layer that is provided on the coating layer and contains a resin binder as a main component.

Hereinafter, “the substrate that is a biaxially stretched polyethylene terephthalate film having a pre-peak temperature of from 160° C. to 225° C. as measured by differential scanning calorimetry (DSC)” may also be referred to as “the substrate of the invention” and “the polyethylene terephthalate film” may also be referred to simply as “PET film.”

“The coating layer that includes a binder containing an acrylic resin, a crosslinked structure part derived from a carbodiimide crosslinking agent, and inorganic fine particles” may also be referred to as “specific coating layer.”

In production of the polyethylene terephthalate (PET) film, in the case of carrying out heat setting through crystallization after stretching, the heat setting temperature was usually as high as about from 230° C. to 240° C. Therefore, the PET film thus obtained had insufficient weather resistance (mainly, hydrolysis resistance). In order to improve hydrolysis resistance, it is effective to adjust the heat setting temperature at the time of heat setting to 210° C. or lower.

However, in the case of setting the heat setting temperature at 210° C. or lower, there was a problem in that although weather resistance is improved, adhesion between the PET film as a substrate and the adhesive layer on the substrate can be impaired. On the other hand, by setting the heat setting temperature at a temperature higher than 210° C., although adhesion between the substrate and the adhesive layer can be improved, weather resistance of the substrate itself is impaired.

On the other hand, adhesion between the substrate and the adhesive layer can be improved without impairing weather resistance by using a biaxially stretched polyethylene terephthalate film having a pre-peak temperature of from 160° C. to 225° C. as measured by differential scanning calorimetry (DSC) is used as the substrate, and providing a coating layer between the substrate and the adhesive layer including a resin binder as a main component, the coating layer including a binder containing an acrylic resin, a crosslinked structure part derived from a carbodiimide crosslinking agent, and inorganic fine particles. The reason for this is unknown, but it is thought that the reason for this is as follows.

Here, the “pre-peak temperature as measured by differential scanning calorimetry (DSC)” is described.

A biaxially stretched polyethylene terephthalate film is usually obtained by melt-extruding a PET raw material as a raw material using an extruder to obtain an unstretched film, thereafter, stretching the unstretched film (may also be referred to as “original sheet”) in a certain direction (direction A), and further stretching the film in a direction different from the direction A (usually a direction orthogonal to the direction A). In a case in which, after stretching the unstretched film, the stretched film is heated and allowed to stand for a while, alignment of the PET molecules is promoted in the film, and physical properties of the film is easily controlled. The procedure including stretching the unstretched film, followed by heating the film in a stretched state, and allowing the film to stand for a while in this manner are referred to as heat setting.

In the invention, the “pre-peak temperature as measured by differential scanning calorimetry (DSC)” is the temperature of the peak which shows up first in the measurement of DSC on the biaxially stretched PET film, and usually corresponds to the maximum film surface temperature (heat setting temperature) of the polyester film during heat setting. Accordingly, the pre-peak temperature of a biaxially stretched polyethylene terephthalate film as measured by differential scanning calorimetry (DSC) of from 160° C. to 225° C. means that in the manufacturing of the substrate, the heat setting is performed in which the maximum film surface temperature (heat setting temperature) is from 160° C. to 225° C.

Conventionally, as described above, when the heat setting temperature is 210° C. or lower, although weather resistance is improved, adhesion between the PET film as the substrate and the adhesive layer on the substrate is impaired. However, it is thought that when a coating layer (specific coating layer) that includes a binder containing an acrylic resin, a crosslinked structure part derived from a carbodiimide crosslinking agent, and inorganic fine particles is provided on the substrate in the invention, the specific coating layer complements the adhesion to the adhesive layer on the substrate, and improves the adhesion.

It is thought that in a case in which a coating liquid including a binder containing an acrylic resin, a carbodiimide crosslinking agent, and inorganic fine particles is applied to the PET film that is the substrate, the carbodiimide crosslinking agent and the carboxy group of the acrylic resin react to form a crosslinked structure part derived from the carbodiimide crosslinking agent, and the carbodiimide crosslinking agent further reacts with the carboxy group of the PET film to form a crosslinked structure part derived from the carbodiimide crosslinking agent, whereby excellent adhesion is given between the specific coating layer and the substrate.

In addition, it is thought that since the binder containing an acrylic resin in the specific coating layer and the resin binder contained in the adhesive layer have similar properties to each other in that they are a resin binder, favorable adhesion between the specific coating layer and the adhesive layer is provided.

Accordingly, excellent adhesion is achieved between the substrate and the adhesive layer, even if a biaxially stretched polyethylene terephthalate film having a pre-peak temperature of 210° C. or lower, which corresponds to a heat setting temperature of 210° C. or lower, is used as the substrate is.

However, in the invention, in a case in which the pre-peak temperature is lower than 160° C., the heat setting temperature is too low to achieve sufficient heat setting, and, therefore, the pre-peak temperature is 160° C. or higher.

On the other hand, as described above, conventionally, when the biaxially stretched polyethylene terephthalate film having a pre-peak temperature higher than 210° C., which corresponds to a heat setting temperature higher than 210° C., was used as the substrate, although favorable adhesion was achieved between the substrate and the adhesive layer, weather resistance of the substrate tended to deteriorate.

However, it is thought that, in the invention, since a specific coating layer is provided on the substrate, weather resistance of the substrate is complemented by the specific coating layer, and thus weather resistance is improved.

In a case in which the PET is exposed to moisture or heat, the demands for weather resistance (mainly hydrolysis resistance) of the substrate (PET) further increase.

It is thought that if the adhesion between the adhesive layer and the substrate is insufficient, when the solar cell backsheet is installed, for example, on the roof, and exposed to direct sunlight or rain, moisture may enter into the space between the adhesive layer and the substrate, and may be heated by sunlight to promote hydrolysis.

On the other hand, it is thought that, in the solar cell backsheet of the invention, as described above, the coating liquid composed of a binder containing an acrylic resin, a carbodiimide crosslinking agent, and inorganic fine particles is applied to the PET film that is the substrate, whereby a crosslinked structure part is formed by the reaction between the binder containing an acrylic resin and the carbodiimide crosslinking agent, and a crosslinked structure part is formed by the reaction between the substrate (PET) and the carbodiimide crosslinking agent.

More specifically, it is thought that since the substrate and the specific coating layer in the invention are firmly bonded and adhered to each other by the crosslinked structure part, there is no space for moisture to enter between the adhesive layer and the substrate even if exposed to rain. In the invention, the specific coating layer and the adhesive layer may be provided on at least one side of the substrate. However, it is thought that if the specific coating layer and the adhesive layer are provided on both sides of the substrate, the substrate is further protected from moisture, and weather resistance is improved.

Accordingly, it is thought that even if a biaxially stretched polyethylene terephthalate film which has a pre-peak temperature higher than 210° C., which corresponds to a heat setting temperature higher than 210° C., is used as the substrate, the substrate has excellent weather resistance.

However, in the invention, in a case in which the pre-peak temperature exceeds 225° C., weather resistance cannot be complemented even if the coating layer in the invention is provided, and, therefore, the pre-peak temperature is 225° C. or lower.

Therefore, it is thought that when a biaxially stretched polyethylene terephthalate film having a pre-peak temperature of 160° C. to 225° C. as measured by differential scanning calorimetry (DSC) is used as the substrate, and the solar cell backsheet has the above-described structure, it is possible to provide the solar cell backsheet with high weather resistance and excellent adhesion between the adhesive layer and the substrate.

In order to improve durability of the substrate, a solid-state polymerized PET having a low acid value may be used as a PET raw material to make the substrate. However, procedures involving solid-state polymerization must be added to the production process. The structure of the solar cell backsheet of the invention does not require processing of the raw material of the substrate, and thus achieves favorable production efficiency.

The substrate, the coating layer, and the adhesive layer of the solar cell backsheet of the invention are described below in detail.

[Substrate]

The substrate of the invention is a biaxially stretched polyethylene terephthalate film having a pre-peak temperature of 160° C. to 225° C. as measured by differential scanning calorimetry (DSC).

Biaxially stretching means stretching an unstretched film in a direction (direction A), followed by stretching in another direction that is different from the direction A (usually a direction orthogonal to the direction A), and, therefore, means that the polyethylene terephthalate film is stretched in two directions.

Details about the method for making the biaxially stretched polyethylene terephthalate film are described below. In general, polyester film is subjected to vertical stretching in which a long sheet of unstretched film is stretched in the conveying direction (MD; machine direction) while the unstretched film is conveyed in the length direction, and lateral stretching in which the unstretched film is stretched in a direction (TD: transverse direction) orthogonal to the machine direction.

As described above, “the pre-peak temperature as measured by differential scanning calorimetry (DSC)” means the peak temperature which shows up first in the differential scanning calorimetry (DSC) of the biaxially stretched PET film, and usually corresponds to the maximum film surface temperature (heat setting temperature) of the polyester film in heat setting.

In the invention, the pre-peak temperature is determined by a common method using a differential scanning calorimeter [DSC-50, manufactured by Shimadzu Co., Ltd.].

In a case in which the pre-peak temperature of the substrate is lower than 160° C., the heat setting temperature is too low to achieve sufficient heat setting, so that the adhesion between the substrate and the adhesive layer cannot be complemented even though a specific coating layer is provided on the substrate of the invention. On the other hand, in a case in which the pre-peak temperature of the substrate is higher than 225° C., although the IV value increases, hydrolysis resistance decreases, so that weather resistance cannot be complemented even though a specific coating layer is provided on the substrate of the invention.

The pre-peak temperature of the biaxially stretched PET film as measured by DSC is preferably from 205° C. to 225° C.

—Intrinsic Viscosity (IV)—

The intrinsic viscosity (IV; Intrinsic viscosity) of the PET film constituting the substrate of the invention is preferably 0.75 dL/g or more. When the IV of the PET film is 0.75 dL/g or more, the PET is resistant to crystallization, and the PET film is resistant to scratching.

In order to further improve the hydrolysis resistance of the PET film thereby improving its weather resistance, the IV value is preferably 0.78 dL/g or more, and more preferably 0.80 dL/g or more.

—Acid Value (AV)—

The acid value (AV) of the PET film constituting the substrate of the invention is preferably from 5 eq/ton to 21 eq/ton. The acid value is more preferably from 6 eq/ton to 20 eq/ton, and even more preferably from 7 eq/ton to 19 eq/ton. The acid value is also referred to as “terminal carboxy group concentration” or “terminal COOH amount”.

In this description, “eq/ton” represents the mole equivalent per 1 ton.

The AV is calculated as follows: a PET film is completely dissolved in a mixed solution of benzyl alcohol/chloroform (=⅔; volume ratio), the solution is titrated with a standard liquid (0.025 N KOH-methanol mixed solution) using phenol red as an indicator, and the AV is calculated from the volume of titration.

—Ratio of Heat Shrinkage—

The ratio of heat shrinkage of the substrate of the invention (heating conditions: heating at 150° C. for 30 minutes) is preferably 2.0% or less. The ratio of heat shrinkage can be, as described below, adjusted to a value within the above-described range by controlling the heating temperature during heat setting and/or heat relaxation in the lateral stretching process (T_{heat setting} and/or T_{heat relaxation}).

The solar cell backsheet of the invention exhibits excellent adhesion between the substrate and the adhesive layer, and is less susceptible to the influence of heat shrinkage of the substrate. In general, the thermal expansion coefficient and the moisture absorption expansion coefficient of PET are greater than those of glass, so that PET tends to be subjected to stress due to temperature and humidity changes, thereby causing cracking or peeling of layers. In a case in which the ratio of heat shrinkage of the substrate of the invention is within the above-described range, cracking of the specific coating layer, which has been formed by application to the substrate of the invention, can be prevented, and more firm adhesion can be achieved between the substrate and the adhesive layer.

The ratio of heat shrinkage is more preferably 1.0% or less, and even more preferably 0.5% or less.

In the invention, the ratio of heat shrinkage means the ratio of shrinkage of the PET film before and after treatment at 150° C. for 30 minutes (unit %; =film length after treatment/film length before treatment×100).

—Substrate Thickness—

The thickness of the substrate of the invention is preferably from 180 μm to 350 μm, more preferably from 200 μm to 320 μm, and even more preferably from 200 μm to 290 μm.

—Molecular Structure of Polyethylene Terephthalate Film—

The PET, which is a raw material of the biaxially stretched polyethylene terephthalate film (PET film) is synthesized by copolymerizing a dicarboxylic acid component with a diol component. The dicarboxylic acid component and the diol component are described below in detail. The PET preferably includes a constituent unit derived from the polyfunctional monomer in which the sum (a+b) of the number of carboxy group (a) and the number of hydroxyl group (b) is three or more (hereinafter may also be referred to as “polyfunctional monomer having three or more functional groups” or merely “polyfunctional monomer”).

As described below, PET is obtained by, for example, esterification reaction and/or interesterification reaction of a dicarboxylic acid component (A) and a diol component (B) by a well-known method, more preferably followed by copolymerization with a polyfunctional monomer having three or more functional groups. Examples and preferred embodiments of the dicarboxylic acid component, the diol component, and the polyfunctional monomer are described below.

—Constituent Unit Derived from Polyfunctional Monomer—

Examples of the constituent unit derived from the polyfunctional monomer in which the sum (a+b) of the number of carboxy group (a) and the number of hydroxyl group (b) is three or more, include, as described below, carboxylic acids in which the number of carboxy group (a) is three or more, ester derivatives thereof and acid anhydrides thereof, polyfunctional monomers in which the number of hydroxyl group is three or more, and “hydroxy acids having both a hydroxyl group and a carboxy group in one molecule, and in which the sum (a+b) of the number of carboxy group (a) and the number of hydroxyl group (b) is three or more”. Examples and preferred embodiments thereof are described below.

Any one obtained by adding, to a carboxy terminal of the carboxylic acid, or a carboxy terminal of the above-described “polyfunctional monomer having both a hydroxyl group and a carboxy group in one molecule”, a hydroxy acid such as l-lactide, d-lactide, hydroxybenzoic acid, derivatives thereof, or any one in which two or more molecules of hydroxy acid are connected may also be preferably used.

One of these compounds may be used singly, or two or more thereof may be used in combination as necessary.

In the PET, the content ratio of the constituent units derived from the polyfunctional monomer having three or more functional groups is preferably from 0.005 mol % to 2.5 mol % with respect to the total constituent units in the PET molecules. The content ratio of the constituent units derived from the polyfunctional monomer is more preferably from 0.020 mol % to 1 mol %, even more preferably from 0.025 mol % to 1 mol %, yet even more preferably from 0.035 mol % to 0.5 mol %, particularly preferably from 0.05 mol % to 0.5 mol %, and most preferably from 0.1 mol % to 0.25 mol %.

In a case in which the constituent unit derived from the polyfunctional monomer having three or more functional groups is present in the PET molecule, a structure in which a polyester chain is branched from the constituent unit derived from the polyfunctional monomer having three or more functional groups is obtained, whereby entanglement between the PET molecules can be promoted. As a result of this, even if the polyester molecules are hydrolyzed by exposure to high temperature and humidity to have lower molecular weight, the entanglement formed between the PET molecules can suppress embrittlement of the PET film, and, therefore, further excellent weather resistance can be achieved. Furthermore, such entanglement is also effective in suppression of heat shrinkage. It is thought that the mobility of the PET molecules is decreased by the entanglement of the PET molecules, so that the molecules cannot be shrunk by heat, whereby heat shrinkage of the PET film is suppressed.

In a case in which the polyfunctional monomer having three or more functional groups is included as a constituent unit, the functional group which has not been used for the polycondensation after the esterification reaction forms a hydrogen bond or covalent bond with a component in the coating layer formed on the PET film by application, whereby the adhesion between the coating layer and the PET film can be maintained in favorable condition, and the occurrence of peeling can be effectively prevented. In the solar cell backsheet of the invention, the adhesive layer is, for example, adhered to a sealing material such as EVA, and the excellent adhesion with little peeling can be exhibited even when used in an environment which is exposed to wind and weather, such as an outdoor environment, for a long time period.

Accordingly, in a case in which the content ratio of the constituent units derived from the polyfunctional monomer having three or more functional groups is 0.005 mol % or more, weather resistance, low heat shrinkability, and adhesion to the specific coating layer formed on the PET film by application can be more readily improved. In a case in which the content ratio of the constituent units derived from the polyfunctional monomer having three or more functional groups is 2.5 mol % or less, hindrance to crystal formation by the bulky constituent units derived from the polyfunctional monomer having three or more functional groups is prevented. As a result of this, formation of low-mobile components formed via the crystals can be promoted, and the decrease of hydrolyzability is prevented. Furthermore, the bulkiness of the constituent units derived from the polyfunctional monomer having three or more functional groups increases the amount of fine asperities on the film surface, whereby the anchoring effect is readily exhibited, and the adhesion between the PET film and the specific coating layer is improved. In addition, the bulkiness suppresses the increase of the free volume (gaps between the molecules), whereby heat shrinkage caused by passing of the PET molecules through the free volume can be suppressed. In addition, the decrease of the glass transition temperature (Tg) caused by excessive addition of the constituent units derived from the polyfunctional monomer having three or more functional groups is also suppressed, whereby the decrease of weather resistance is effectively prevented.

—Structure Part Derived from Terminal Blocking Agent—

It is preferable that the PET film further has a structure part derived from a terminal blocking agent selected from an oxazoline compound, a carbodiimide compound, or an epoxy compound. The “structure part derived from a terminal blocking agent” means the structure in which the terminal blocking agent is bonded to the terminal of a PET molecule by reaction between the terminal blocking agent and the carboxylic acid at the terminal of the PET molecule.

In a case in which the terminal blocking agent is included in the PET film, the terminal blocking agent reacts with the carboxylic acid at the terminal of PET molecules, whereby the terminal blocking agent is bonded to the terminal of PET molecules. Accordingly, the acid value (amount of terminal COOH) of the PET film is readily and stably maintained at the intended value, such as a value in the above-described preferred range. More specifically, hydrolysis of the PET promoted by the terminal carboxylic acid can be suppressed, and weather resistance can be maintained at a high level. In addition, since the terminal blocking agent is bonded to the terminal of PET molecules to bulk up the terminal part of the chain, so that the amount of fine asperities on the film surface increases. Therefore, anchoring effect is readily expressed, and the adhesion between the PET film and the specific coating layer formed on the film by application is improved. In addition, the terminal blocking agent is bulky, and thus suppresses the movement of the PET molecules by passing of the PET molecules through the free volume. As a result of this, the inclusion of the terminal blocking agent also provides an effect of suppression of heat shrinkage associated with the movement of molecules.

The terminal blocking agent is an additive for decreasing the amount of terminal carboxyl groups in the polyester through the reaction with the terminal carboxy groups of the PET molecules.

The terminal blocking agent may be used singly or in combination of two or more thereof.

The content of the terminal blocking agent is preferably from 0.1% by mass to 5% by mass, more preferably from 0.3% by mass to 4% by mass, and even more preferably from 0.5% by mass to 2% by mass, with respect to the mass of the PET film.

When the content ratio of the terminal blocking agent in the PET film is 0.1% by mass or more, excellent adhesion to the specific coating layer can be provided, weather resistance can be improved by the AV decrease effect, and low heat shrinkability can also be imparted. In a case in which the content ratio of the terminal blocking agent in the PET film is 5% by mass or less, excellent adhesion to the coating layer can be provided, and the decrease in the glass transition temperature (Tg) of the PET caused by the addition of the terminal blocking agent can be suppressed, whereby the deterioration in weather resistance and the increase in heat shrinkage caused therefor can be suppressed. This is because increase in hydrolyzability caused by relative increase of reactivity of the PET due to the decrease in Tg is suppressed, and heat shrinkage caused by the increase in mobility of PET molecules due to the Tg decrease is prevented.

The terminal blocking agent in the invention is preferably a compound having a carbodiimide group, an epoxy group, or an oxazoline group. Specific examples of the preferred terminal blocking agent include carbodiimide compounds, epoxy compounds, and oxazoline compounds.

Examples of the carbodiimide compound having a carbodiimide group include monofunctional carbodiimide and polyfunctional carbodiimide Examples of the monofunctional carbodiimide include dicyclohexylcarbodiimide, diisopropyl carbodiimide, dimethylcarbodiimide, diisobutyl carbodiimide, dioctyl carbodiimide, t-butyl isopropyl carbodiimide, diphenyl carbodiimide, di-t-butyl carbodiimide and di-β-naphthyl carbodiimide Of these examples, preferable examples include dicyclohexylcarbodiimide and diisopropyl carbodiimide.

The polyfunctional carbodiimide is preferably polycarbodiimide having a degree of polymerization of from 3 to 15. The polycarbodiimide generally includes a repeating unit represented by, for example, “—R—N═C═N—”, wherein R represents a divalent linking group such as alkylene or arylene. Examples of the repeating unit include 1,5-naphthalene carbodiimide, 4,4′-diphenylmethane carbodiimide, 4,4′-diphenyl dimethylmethane carbodiimide, 1,3-phenylene carbodiimide, 2,4-tolylene carbodiimide, 2,6-tolylene carbodiimide, the mixture of 2,4-tolylene carbodiimide and 2,6-tolylene carbodiimide, hexamethylene carbodiimide, cyclohexane-1,4-carbodiimide, xylylene carbodiimide, isophorone carbodiimide, dicyclohexyl methane-4,4′-carbodiimide, methylcyclohexane carbodiimide, tetramethylxylylene carbodiimide, 2,6-diisopropylphenyl carbodiimide, and 1,3,5-triisopropylbenzene-2,4-carbodiimide.

The carbodiimide compound preferably has high heat resistance, from the point of suppressing the generation of isocyanate gas caused by pyrolysis. In order to increase heat resistance, the molecular weight (degree of polymerization) is preferably higher, and it is more preferred that the terminal the carbodiimide compound has a structure that is highly resistant to heat. By lowering a temperature of the melt extrusion of the polyester material resin, the effect of improving the whether resistance and the effect of lowering the thermal shrinkage can be more effectively exhibited.

In the PET film in which a carbodiimide compound is used, the amount of isocyanate gase generated is preferably from 0 to 0.02% by mass when the PET film is kept at a temperature of 300° C. for 30 minutes. When the amount of the generated isocyanate gas is 0.02% by mass or less, little bubbles (voids) are formed in the PET film, so that a portion of stress concentration hardly occurs, whereby destruction and exfoliation, which tend to occur within the PET film, can be prevented. As a result of this, excellent adhesion to the adjacent material can be exhibited.

The isocyanate gas is a gas having an isocyanate group, and examples thereof include diisopropylphenyl isocyanate, 1,3,5-triisopropylphenyl diisocyanate, 2-amino-1,3,5-triisopropylphenyl-6-isocyanate, 4,4′-dicyclohexyl methane diisocyanate, isophorone diisocyanate, and cyclohexyl isocyanate.

Examples of the preferred epoxy compound having an epoxy group include glycidyl ester compounds and glycidyl ether compounds.

Specific examples of the glycidyl ester compounds include, benzoic acid glycidyl ester, t-Bu-benzoic acid glycidyl ester, p-toluic acid glycidyl ester, cyclohexane carboxylic acid glycidyl ester, pelargonic acid glycidyl ester, stearic acid glycidyl ester, lauric acid glycidyl ester, palmitic acid glycidyl ester, behenic acid glycidyl ester, versatic acid glycidyl ester, oleic acid glycidyl ester, linolic acid glycidyl ester, linoleic acid glycidyl ester, behenolic acid glycidyl ester, stearolic acid glycidyl ester, terephthalic acid diglycidyl ester, isophthalic acid diglycidyl ester, phthalic acid diglycidyl ester, naphthalenedicarboxylic acid diglycidyl ester, methylterephthalic acid diglycidyl ester, hexahydrophthalic acid diglycidyl ester, tetrahydrophthalic acid diglycidyl ester, cyclohexane dicarboxylic acid diglycidyl ester, adipic acid diglycidyl ester, succinic acid diglycidyl ester, sebacic acid diglycidyl ester, dodecane dione acid diglycidyl ester, octadecane dicarboxylic acid diglycidyl ester, trimellitic acid triglycidyl ester and pyromellitic acid tetraglycidyl ester.

Specific examples of the glycidyl ether compound include, phenyl glycidyl ether, o-phenyl glycidyl ether, and bisglycidyl polyether obtained by the reaction of bisphenol such as 1,4-bis(β,γ-epoxy propoxy)butane, 1,6-bis(β,γ-epoxy propoxy)hexane, 1,4-bis(β,γ-epoxy propoxy)benzene, 1-(β,γ-epoxypropoxy)-2-ethoxy ethane, 1-(β,γ-epoxypropoxy)-2-benzyloxy ethane, 2,2-bis-[p-(β,γ-epoxypropoxy)phenyl]propane, 2,2-bis-(4-hydroxyphenyl)propane, or 2,2-bis-(4-hydroxyphenyl)methane with epichlorohydrin.

The oxazoline compound may be selected from as appropriate from the compounds having an oxazoline group, and is preferably a bisoxazoline compound.

Examples of the bisoxazoline compound include, 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline), 2,2′-bis(4-cyclohexyl-2-oxazoline), 2,2′-bis(4-benzyl-2-oxazoline), 2,2′-p-phenylene bis(2-oxazoline), 2,2′-m-phenylene bis(2-oxazoline), 2,2′-o-phenylene bis(2-oxazoline), 2,2′-p-phenylene bis(4-methyl-2-oxazoline), 2,2′-p-phenylene bis(4,4-dimethyl-2-oxazoline), 2,2′-m-phenylene bis(4-methyl-2-oxazoline), 2,2′-m-phenylene bis(4,4-dimethyl-2-oxazoline), 2,2′-ethylene bis(2-oxazoline), 2,2′-tetramethylene bis(2-oxazoline), 2,2′-hexamethylene bis(2-oxazoline), 2,2′-octamethylene bis(2-oxazoline), 2,2′-decamethylene bis(2-oxazoline), 2,2′-ethylene bis(4-methyl-2-oxazoline), 2,2′-tetramethylene bis(4,4-dimethyl-2-oxazoline), 2,2′-9,9′-diphenoxyethane bis(2-oxazoline), 2,2′-cyclohexylene bis(2-oxazoline) and 2,2′-diphenylene bis(2-oxazoline). Among them, 2,2′-bis(2-oxazoline) is most preferred because it shows favorable reactivity to PET, and highly improves weather resistance.

The bisoxazoline compound may be used singly or in combination of two or more thereof, as long as the effect of the invention will not be impaired.

In the invention, the polyfunctional monomer having three or more functional groups and the terminal blocking agent, which are described above or below, each may be used singly or in combination of two or more thereof.

The method for producing the substrate of the invention is described below in detail.

[Coating Layer (Specific Coating Layer)]

The coating layer (specific coating layer) included in the solar cell backsheet of the invention is a layer which is provided at at least one side of the substrate in the invention, and includes a binder containing an acrylic resin, a crosslinked structure part derived from a carbodiimide crosslinking agent, and inorganic fine particles.

As necessary, the coating layer may further contain, for example, a surfactant and/or an antioxidant.

Specific coating layer is provided at at least one side of the substrate in the invention. More specifically, the coating layer may be provided at one or both sides of the substrate in the invention.

—Binder containing acrylic resin—

The binder included in the specific coating layer contains at least an acrylic resin, and may further contain a resin other than the acrylic resin.

The binder in the specific coating layer contains at least an acrylic resin having a carboxy group which reacts with the below-described carbodiimide crosslinking agent, and having high durability, so that the binder is crosslinked by the carbodiimide crosslinking agent, and the layer has high durability even in a humid and hot temperature environment such as an outdoor environment in which the substrate is exposed to rain.

The acrylic resin may be an acrylic resin which is obtained using a known acrylic monomer, and may further contain another acrylic monomer as a copolymerization component, and examples of the acrylic monomer include (meth)acrylates such as methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, n-hexyl (meth)acrylate, 2-ethylhexyl(meth)acrylate, acetoxyethyl (meth)acrylate, phenyl (meth)acrylate, 2-methoxyethyl(meth)acrylate, 2-ethoxyethyl(meth)acrylate, 2-(2-methoxyethoxy)ethyl(meth)acrylate, cyclohexyl (meth)acrylate, benzyl (meth)acrylate, diethylene glycol monomethyl ether (meth)acrylate, diethylene glycol monoethyl ether (meth)acrylate, diethylene glycol monophenyl ether (meth)acrylate, triethylene glycol monomethyl ether (meth)acrylate, triethylene glycol monoethyl ether (meth)acrylate, dipropylene glycol monomethyl ether (meth)acrylate, polyethylene glycol monomethyl ether (meth)acrylate, polypropylene glycol monomethyl ether (meth)acrylate, monomethyl ether (meth)acrylate which is a copolymer of ethylene glycol and propylene glycol, N,N-dimethylaminoethyl(meth)acrylate, N,N-diethylaminoethyl(meth)acrylate, and N,N-dimethylaminopropyl(meth)acrylate.

Examples of the other resin which may be used in combination with the acrylic resin include a polyester resin, an urethane resin (polyurethane), an acrylic resin (polyacryl), an olefin resin (polyolefin), a vinyl alcohol resin (polyvinyl alcohol), and a silicone resin.

The acrylic resin contained in the specific coating layer may be used singly or in combination of two or more thereof. The other resin which may be used in combination with the acrylic resin may be used singly or in combination of two or more thereof.

The content of the binder in the specific coating layer is preferably decided in consideration of the mass ratio to the below-described carbodiimide crosslinking agent, and is preferably from 0.02 g/m² to 0.1 g/m². When the content of the binder is within the range, the effect of the invention can be further enhanced.

When the resin other than the acrylic resin is used in combination with the acrylic resin, the content of acrylic resin in the total binder contained in the specific coating layer is preferably 70% by mass or more, and more preferably 80% by mass or more with respect to the total binder mass. Further, all the binder contained in the specific coating layer is preferably an acrylic resin.

—Crosslinked Structure Part Derived from Carbodiimide Crosslinking Agent—

The specific coating layer includes a crosslinked structure part derived from a carbodiimide crosslinking agent.

The specific coating layer may be formed, as described below, applying a coating liquid for forming the specific coating layer to the substrate of the invention to obtain a coating film, followed by drying the film. The coating liquid for forming the specific coating layer contains, at least, the above-described binder containing an acrylic resin, the above-described carbodiimide crosslinking agent, and the below-described inorganic fine particles. The carbodiimide crosslinking agent in the coating liquid reacts with the acrylic resin in the binder, and, when the specific coating layer is formed, the specific coating layer includes a crosslinked structure part in which binder molecules are crosslinked together. The crosslinked structure part is derived from the carbodiimide crosslinking agent.

As described above, the molecules of the binder containing an acrylic resin and having high durability are crosslinked, whereby the specific coating layer has high durability even in a humid and hot environment.

In the invention, the carbodiimide crosslinking agent further reacts with the terminal carboxy group of the PET film that is the substrate of the invention, whereby the binder in the specific coating layer and the PET film are also crosslinked together, and thus a crosslink structure part derived from the carbodiimide crosslinking agent is developed. The crosslinking between the binder in the specific coating layer and the PET film markedly contributes to the excellent adhesion between the adhesive layer and the substrate. In addition, it is thought that the crosslinking between the in highly durable binder in the specific coating layer and the PET film inhibits the entry of moisture into the space between the substrate and the adhesive layer, whereby weather resistance of the substrate is likely maintained.

Examples of the carbodiimide crosslinking agent composing the crosslinked structure part derived from the carbodiimide crosslinking agent include the carbodiimide compound which may be contained in the above-described PET film that is the substrate of the invention. Specific examples include monofunctional carbodiimides and polyfunctional carbodiimides.

Examples of the monofunctional carbodiimide include dicyclohexyl carbodiimide, diisopropyl carbodiimide, dimethyl carbodiimide, diisobutyl carbodiimide, dioctyl carbodiimide, t-butylisopropyl carbodiimide, diphenyl carbodiimide, di-t-butyl carbodiimide, and di-β-naphthyl carbodiimide Among them, dicyclohexylcarbodiimide and diisopropyl carbodiimide are preferred.

Examples of the preferred polyfunctional carbodiimide include polycarbodiimides having a degree of polymerization of from 3 to 15. The polycarbodiimide generally has a repeating unit represented by, for example, “—R—N═C═N—”, wherein R represents a divalent linking group such as alkylene or arylene. Examples of the repeating unit include 1,5-naphthalene carbodiimide, 4,4′-diphenylmethane carbodiimide, 4,4′-diphenyldimethylmethane carbodiimide, 1,3-phenylene carbodiimide, 2,4-tolylene carbodiimide, 2,6-tolylene carbodiimide, the mixture of 2,4-tolylene carbodiimide and 2,6-tolylene carbodiimide, hexamethylene carbodiimide, cyclohexane-1,4-carbodiimide, xylylene carbodiimide, isophorone carbodiimide, dicyclohexyl methane-4,4′-carbodiimide, methylcyclohexane carbodiimide, tetramethylxylylene carbodiimide, 2,6-diisopropylphenyl carbodiimide, and 1,3,5-triisopropylbenzene-2,4-carbodiimide.

The carbodiimide crosslinking agent contained in the specific coating layer may be used singly or in combination of two or more thereof.

The content of the crosslinked structure part derived from the carbodiimide crosslinking agent in the specific coating layer is preferably decided in consideration of the mass ratio to the acrylic resin in the above-described binder, and is preferably within the range which satisfy the below-described formula (1).

The content of the crosslinked structure part derived from the carbodiimide crosslinking agent in the specific coating layer corresponds to the content in the coating liquid for forming the specific coating layer. Accordingly, the content of the carbodiimide crosslinking agent in the coating liquid for forming the specific coating layer is preferably within the range decided from the below-described formula (1).

—Inorganic Fine Particles—

The specific coating layer includes inorganic fine particles.

The inclusion of the inorganic fine particles in the specific coating layer enhances the adhesiveness between the substrate and the adhesive layer of the solar cell backsheet.

The inorganic fine particles which may be contained in the specific coating layer are not particularly limited, and examples thereof include clay, mica, titanium oxide, tin oxide, calcium carbonate, kaolin, talc, wet silica, dry silica, colloidal silica, calcium phosphate, barium sulfate, alumina, and zirconia.

Among them, silica (examples thereof including wet silica, dry silica, and colloidal silica), titanium oxide, alumina, and tin oxide are preferred, and tin oxide or silica is preferred, because the lowering in adhesion when exposed to a humid and hot atmosphere is small. Among them, tin oxide is particularly preferred.

It is thought that the particle shape of tin oxide is more often indefinite than that of silica, so that tin oxide has relatively greater surface properties and tends to form secondary and tertiary particles to form complicated grain aggregates, whereby the binding between the tin oxide particles and binder resin are more firmly maintained than the binding between silica particles and the binder resin.

It has been found that particularly excellent adhesion is provided between the adhesive layer and the substrate of the invention when the specific coating layer is formed by applying the coating liquid containing an acrylic resin, tin oxide, and the carbodiimide crosslinking agent to the substrate of the invention.

In the specific coating layer, one kind of the inorganic fine particles may be included singly or two more kinds thereof may be included in combination. In a case in which two or more kinds of inorganic fine particles are used, at least one kind of them is preferably tin oxide, and it is more preferred that the main component of the inorganic fine particles be tin oxide. Here, “main component” means that the mass of tin oxide is more than 50% by mass with respect to the total mass of the inorganic fine particles in the specific coating layer. The content ratio of tin oxide with respect to the total mass of the inorganic fine particles is preferably 70% by mass or more, and more preferably 90% by mass or more.

It is particularly preferred that the inorganic fine particles which may be contained in the specific coating layer are tin oxide only.

The content of the inorganic fine particles in the specific coating layer is preferably from 50% by mass to 500% by mass with respect to the total mass of the binder in the specific coating layer. In this case, the main component of the inorganic fine particles is preferably tin oxide.

When the content of the inorganic fine particles in the specific coating layer is 50% by mass or more with respect to the total mass of the binder in the specific coating layer, weather resistance and the adhesion between the adhesive layer and the substrate can be enhanced.

In general, when the content of the inorganic fine particles is as high as 100% by mass or more with respect to the total mass of the binder contained in the same layer, adhesion to the adjacent layer tends to be impaired. However, excellent adhesion can be provided due to the combination of the binder, carbodiimide crosslinking agent, and inorganic fine particles contained in the specific coating layer, whereby the concentration of the inorganic fine particles can be increased up to 500% by mass. In particular, the combination of the acrylic resin, carbodiimide crosslinking agent, and tin oxide provides particularly excellent adhesion between the adhesive layer and the substrate of the invention. Therefore, in a case in which the main component of the inorganic fine particles is tin oxide, excellent adhesion is provided between the adhesive layer and the substrate of the invention, even if the content of the inorganic fine particles to the binder is 500% by mass.

In a case in which the content of the inorganic fine particles to the binder is 500% by mass or less, the specific coating layer is less likely to become powdery, and the adhesion between the adhesive layer and the substrate of the invention is less likely to be impaired.

The content of the inorganic fine particles in the specific coating layer is more preferably from 100% by mass to 400% by mass, and even more preferably from 150% by mass to 300% by mass, with respect to the total mass of the binder in the specific coating layer.

The particle size of the inorganic fine particles is not particularly limited, but is preferably from about 10 nm to about 700 nm, and more preferably from about 20 nm to about 300 nm from the viewpoint of adhesion. The shape of the fine particles is not particularly limited, and may be, for example, spherical, indefinite, or needle.

—Formula (1)—

In the solar cell backsheet of the invention, when the acid value of the acrylic resin in the specific coating layer is expressed as A, and the equivalent of the carbodiimide crosslinking agent is expressed as B, the mass ratio X of the carbodiimide crosslinking agent to the acrylic resin (carbodiimide crosslinking agent/acrylic resin) preferably satisfies the following formula (1) with the product AB of A and B (=A×B).

(0.8AB)/56100<X<(2.0AB)/56100 (1)

The acid value A of the acrylic resin is the number of milligrams of potassium hydroxide necessary for neutralizing the free fatty acid contained in 1 g of acrylic resin.

The equivalent B of the carbodiimide crosslinking agent is the number of grams of the carbodiimide compound containing 1 mole of carbodiimide group.

In the formula (1), “56100” represents the value obtained by multiplying the weight average molecular weight 56.1 of potassium hydroxide (KOH), which is used for measuring the acid value of the acrylic resin, by 1000 (56.1×1000=56100), and “AB/56100” represents the ratio of the acrylic resin to the carbodiimide crosslinking agent at which the number of moles of the acid in the acrylic resin and the number of moles of the carbodiimide group in the carbodiimide crosslinking agent is equivalent.

The carbodiimide equivalent B of the carbodiimide crosslinking agent is preferably from 200 to 500.

—Surfactant—

The specific coating layer may further include a surfactant.

Examples of the surfactant include known anionic and nonionic surfactants. The content of the surfactant in the specific coating layer is preferably from 0.1 mg/m² to 15 mg/m², and more preferably from 0.5 m g/m² to 5 mg/m².

Inclusion of the surfactant in the amount within the above-described range in the coating liquid for forming the specific coating layer can suppress the occurrence of cissing to allow favorable formation of the layer, whereby the effect of the invention can be further improved.

—Other Additive—

The specific coating layer may contain any of various additives within the range which will not impair the object of the invention. Examples of the additives include ultraviolet absorbers, light stabilizers, and antioxidants.

—Method for Forming Specific Coating Layer—

The specific coating layer is formed by applying the coating liquid for forming the specific coating layer, which contains a binder, a crosslinking agent, inorganic fine particles, and as necessary other components, in the above-described amounts, to at least one side of the substrate of the invention.

Examples of the coating method include known methods using, for example a gravure coater or a bar coater.

The coating liquid may be aqueous-based one in which water is used as a coating solvent, or a solvent-based one in which an organic solvent such as toluene or methyl ethyl ketone is used. From the viewpoint of environment load, the solvent is preferably water. The coating solvent may be used singly or in combination of two or more thereof. Examples of the preferred coating solvent include water and water/methyl alcohol=95/5 (mass ratio).

Before applying the coating liquid to the substrate of the invention, the substrate surface may be subjected to surface treatment such as acid etching treatment using the mixture of sulfuric acid and chromic acid, flame treatment using gas flame, ultraviolet irradiation treatment, corona discharge treatment, or glow discharge treatment.

The thickness of the specific coating layer is not particularly limited, but is preferably from 0.2 μm to 8.0 μm, and preferably from 0.5 μm to 6.0 μm.

The specific coating layer may have monolayer structure composed of one layer, or may have a multilayer structure composed of two or more layers. In a case in which the specific coating layer has a multilayer structure, The total thickness of the specific coating layer composed of two or more layers is preferably from 0.2 μm to 8.0 μm.

[Adhesive Layer]

The solar cell backsheet of the invention include an adhesive layer on the above-described specific coating layer.

The adhesive layer includes at least one resin binder as a main component.

“To include a resin binder as a main component” means that the adhesive layer includes a resin binder in a proportion which exceeds 50% by mass of the solid mass of the adhesive layer.

Examples of the resin binder which may be contained in the adhesive layer include polyester, polyurethane, acrylic resins, and polyolefin. The acrylic resins may be a composite resin of acryl and silicone. In particular, from the viewpoint of durability, acrylic resins and polyolefin are preferred, and acrylic resins are more preferred from the viewpoint of adhesion to the specific coating layer containing an acrylic resin.

The amount of the resin binder in the adhesive layer is preferably from 0.05 g/m² to 5 g/m², and particularly preferably from 0.08 g/m² to 3 g/m². In a case in which the amount of the binder is 0.05 g/m² or more, favorable adhesion force can be provided, and in a case in which the amount is 5 g/m² or less, favorable surface properties can be obtained.

It is preferable that the adhesive layer further contains the crosslinked structure part derived from the crosslinking agent.

Examples of the crosslinking agent composing the crosslinked structure part include epoxy crosslinking agents, isocyanate crosslinking agents, melamine crosslinking agents, carbodiimide crosslinking agents, and oxazoline crosslinking agents. Among them, epoxy crosslinking agents are preferred. Any commercially available epoxy crosslinking agent may be used, and examples thereof include DENACOL EX-614B manufactured by Nagase ChemteX Corporation.

The content of the crosslinked structure part derived from the crosslinking agent in the adhesive layer is preferably from 5% by mass to 50% by mass, and more preferably from 20% by mass to 40% by mass, with respect to the total binder mass in the adhesive layer. In a case in which the content of the crosslinked structure part is 5% by mass or more, favorable crosslinking effect can be obtained, and the decrease in the strength of the adhesive layer or poor adhesion are less likely to occur, and in a case in which the content is 50% by mass or less, the coating liquid has a longer pot life when applied to form the adhesive layer.

The content of the crosslinked structure part derived from the crosslinking agent in the adhesive layer corresponds to the content in the coating liquid for forming the adhesive layer. Accordingly, the content of the crosslinking agent in the coating liquid for forming the adhesive layer is preferably from 5% by mass to 50% by mass with respect to the total binder mass in the coating liquid.

The adhesive layer may further contain, as necessary, fine particles and other additives.

Examples of the fine particles include inorganic fine particles such as silica, calcium carbonate, magnesium oxide, magnesium carbonate, and tin oxide.

Examples of the other additives include known matting agents such as polystyrene, polymethyl methacrylate, and silica, known anionic surfactants and known nonionic surfactants.

—Method for Forming Adhesive Layer—

The adhesive layer may be a sheet-like member containing at least one resin binder as a main component, or a coating layer formed by applying an adhesive layer-forming coating liquid, which contains at least one resin binder as a main component, to the specific coating layer. In a case in which the adhesive layer is a sheet-like member containing at least one resin binder as a main component, the sheet-like member alone may be bonded to the specific coating layer, or a known adhesive may be applied between the specific coating layer and the member.

The method by application is preferred because it is simple and can form a thin and highly uniform film.

The resin binder and the crosslinking agent, which may be contained as necessary, may be contained in the coating liquid for forming the adhesive layer to give the above-described content.

Examples of the method for applying the coating liquid include known methods using, for example, a gravure coater or a bar coater. The solvent of the coating liquid used for application may be water or an organic solvent such as toluene or methyl ethyl ketone. The solvent may be used singly or in combination of two or more thereof.

[Other Layer]

The solar cell backsheet may be any solar cell backsheet including the above-described specific coating layer and adhesive layer at at least one side of the substrate in the invention, and may further include a reflecting layer for reflecting daylight, or a color layer for imparting the aesthetic quality to the solar cell backsheet.

The reflecting layer may include, for example, a white pigment such as titanium oxide, and the color layer generally contains a black pigment or a blue pigment.

As described above, the solar cell backsheet of the invention includes the substrate of the invention, the specific coating layer, and the adhesive layer, thereby achieving both weather resistance and adhesion.

Accordingly, the solar cell backsheet of the invention has a high retention ratio of elongation at break in a humid and hot environment. For example, the retention ratio of elongation at break is from 20% to 90% before and after the acceleration test wherein the sheet is allowed to stand in an environment at 120° C. at a relative humidity of 100% (also expressed as 100% RH) for 48 hours.

The above-described retention ratio of elongation at break is specifically calculated as follows.

Firstly, the solar cell backsheet before the above-described acceleration test and the solar cell backsheet after the acceleration test are measured for the elongation at break by the method in accordance with JIS-K7127. The retention ratio of elongation at break is calculated from the following formula (L), wherein the L_{before} is the elongation at break of the solar cell backsheet before the acceleration test, and L_{after} is the elongation at break of the solar cell backsheet after the acceleration test.

Retention ratio [%] of elongation at break=(L_{after}/L_{before})×100 Formula (L)

<Method for Producing Substrate>

The substrate of the invention may be produced by any method as long as the above-described pre-peak temperature may be achieved. In the invention, for example, the substrate is most favorably produced using the below-described method for producing a substrate of the invention.

The method of the invention for producing a substrate is specifically described below.

The method of the invention for producing a substrate includes at least a film forming process of melt-extruding a raw PET resin into a sheet form, and then cooling the sheet on a casting drum to form a PET film, a vertical stretching process of vertically stretching the PET film thus formed in a longitudinal direction, and a lateral stretching process of laterally stretching the PET film after the vertical stretching in a width direction orthogonal to the vertical direction, wherein the lateral stretching process includes a preheating process of preheating the PET film after the vertical stretching to a temperature at which the film can be stretched, a stretching process of laterally stretching the preheated PET film in a width direction orthogonal to the longitudinal direction under tension, a heat setting process of heating to attain the maximum film surface temperature of the PET film after the vertical and lateral stretching of 160° C. to 225° C. for heat setting, a heat relaxation process of heating the heat-set PET film to relax the tension on the PET film, and a cooling process of cooling the PET film after heat relaxation.

Details about the method for producing the PET film of the invention are described below, for each of the film forming process, vertical stretching process, and lateral stretching process.

[Film Forming Process]

In the film forming process, the raw PET resin is melt-extruded in a sheet form, and cooled on a casting drum (also referred to as “chill roll”, or “cooling roll”) to form a PET film. In the invention, a PET film having an intrinsic viscosity (IV) of 0.75 dL/g or more is favorably formed.

The method for the melt extrusion of the raw PET resin, and the raw PET resin are not particularly limited, but the intended intrinsic viscosity can be achieved by appropriately selecting the catalyst used for the synthesis of the raw PET resin and the polymerization method.

Firstly, the raw PET resin is described below.

(Raw PET Resin)

The raw PET resin is not particularly limited as long as it is a raw material of a PET film and contains PET, and may further contain, in addition to PET, a slurry of inorganic or organic particles. The raw PET resin may contain a titanium element derived from the catalyst.

The type of the PET contained in the raw PET resin is not particularly limited.

The PET may be synthesized from a dicarboxylic acid component and a diol component, or may be a commercially available PET.

When PET is synthesized, for example, a dicarboxylic acid component (A) and a diol component (B) are subjected to esterification reaction and/or interesterification reaction by a well-known method.

(A) Examples of the dicarboxylic acid component include dicarboxylic acids such as: aliphatic dicarboxylic acids such as malonic acid, succinic acid, glutaric acid, adipic acid, suberic acid, sebacic acid, dodecane dione acid, dimer acid, eicosane dione acid, pimelic acid, azelaic acid, methylmalonic acid, and ethylmalonic acid; alicyclic dicarboxylic acids such as adamantane dicarboxylic acid, norbornene dicarboxylic acid, isosorbide, cyclohexane dicarboxylic acid, and decalin dicarboxylic acid; aromatic dicarboxylic acids such as terephthalic acid, isophthalic acid, phthalic acid, 1,4-naphthalenedicarboxylic acid, 1,5-naphthalenedicarboxylic acid, 2,6-naphthalenedicarboxylic acid, 1,8-naphthalenedicarboxylic acid, 4,4′-diphenyl dicarboxylic acid, 4,4′-diphenyl ether dicarboxylic acid, sodium 5-sulfoisophthalate, phenyl indan dicarboxylic acid, anthracene dicarboxylic acid, phenanthrene dicarboxylic acid, 9,9′-bis(4-carboxy phenyl) fluorene acid; and their ester derivatives.

(B) Examples of the diol component include diol compounds such as: aliphatic diols such as ethylene glycol, 1,2-propanediol, 1,3-propanediol, 1,4-butanediol, 1,2-butanediol, and 1,3-butanediol; alicyclic diols such as cyclohexane dimethanol, spiro glycol, isosorbide; and aromatic diols such as bisphenol A, 1,3-benzene dimethanol, 1,4-benzene dimethanol, and 9,9′-bis(4-hydroxyphenyl) fluorene.

As the dicarboxylic acid component (A), at least one aromatic dicarboxylic acid is preferably used. It is more preferable that an aromatic dicarboxylic acid as a main component among dicarboxylic components. The dicarboxylic acid component (A) may further contain a dicarboxylic acid component other than aromatic dicarboxylic acid. Examples of such a dicarboxylic acid component include ester derivatives of, for example, an aromatic dicarboxylic acid.

Here “to include an aromatic dicarboxylic acid as a main component” means that the proportion of the aromatic dicarboxylic acid in the dicarboxylic acid component is 80% by mass or more.

The diol component (B) is preferably at least one aliphatic diol. The aliphatic diol may include ethylene glycol, and preferably includes ethylene glycol as a main component.

The main component means that the proportion of ethylene glycol in the diol component is 80% by mass or more.

The usage of the diol component (for example, ethylene glycol) is preferably from 1.015 to 1.50 mol with respect to 1 mol of the dicarboxylic acid component (specifically the above-described aromatic dicarboxylic acid such as terephthalic acid) and its ester derivative as necessary. The usage is more preferably from 1.02 to 1.30 mol, and more preferably from 1.025 to 1.10 mol. In a case where the usage is 1.015 or more, esterification reaction favorably proceeds, and in a case where the usage is 1.50 mol or less, incidental production of diethylene glycol caused by, for example dimerization of ethylene glycol, can be suppressed, whereby many properties such as melting point, glass transition temperature, crystallinity, heat resistance, hydrolysis resistance, and weather resistance can be maintained at favorable levels.

In the invention, the raw PET resin preferably contains a polyfunctional monomer in which the sum (a+b) of the number of carboxyl group (a) and the number of hydroxyl group (b) is three or more, as a copolymerization component (constituent component having three or more functional groups). “To contain a polyfunctional monomer as a copolymerization component (constituent component having three or more functional groups)” means that it contains a constituent unit derived from a polyfunctional monomer.

Examples of the constituent unit derived from the polyfunctional monomer, in which the sum (a+b) of the number of carboxy group (a) and the number of hydroxyl group (b) is three or more, include the below-described constituent units derived from carboxylic acids.

Examples of a carboxylic acid in which the number of carboxy group (a) is 3 or more (polyfunctional monomer) include: trifunctional aromatic carboxylic acids such as trimesic acid, trimellitic acid, pyromellitic acid, naphthalene tricarboxylic acid, and anthracene tricarboxylic acid; trifunctional aliphatic carboxylic acids such as methane tricarboxylic acid, ethane tricarboxylic acid, propane tricarboxylic acid, and butane tricarboxylic acid; tetrafunctional aromatic carboxylic acids such as benzene tetracarboxylic acid, benzophenone tetracarboxylic acid, naphthalenetetracarboxylic acid, anthracene tetracarboxylic acid, and perylene tetracarboxylic acid; tetrafunctional aliphatic carboxylic acids such as ethane tetracarboxylic acid, ethylene tetracarboxylic acid, butane tetracarboxylic acid, cyclopentane tetracarboxylic acid, cyclohexane tetracarboxylic acid, and adamantane tetracarboxylic acid; aromatic carboxylic acids having five or more functional groups such as benzenepentacarboxylic acid, benzene hexacarboxylic acid, naphthalene pentacarboxylic acid, naphthalene hexacarboxylic acid, naphthalene heptacarboxylic acid, naphthalene octacarboxylic acid, anthracene pentacarboxylic acid, anthracene hexacarboxylic acid, anthracene heptacarboxylic acid, and anthracene octacarboxylic acid; aliphatic carboxylic acid having five or more functional groups such as ethane pentacarboxylic acid, ethane heptacarboxylic acid, butane pentacarboxylic acid, butane heptacarboxylic acid, cyclopentane pentacarboxylic acid, cyclohexane pentacarboxylic acid, cyclohexane hexacarboxylic acid, adamantane pentacarboxylic acid, and adamantane hexacarboxylic acid.

In the invention, these esters, acid anhydrides and the like are mentioned as examples, however, the carboxylic acid having a number of carboxy group (a) of 3 or more in the invention is not limited to the above.

Any compound obtained by adding, to a terminal of any of the above-described carboxylic acid, a hydroxy acid such as l-lactide, d-lactide, hydroxybenzoic acid, derivatives thereof, or any one in which two or more molecules of hydroxy acid are connected may also be preferably used.

One of these compounds may be used singly or two or more thereof may be used in combination as necessary.

Examples of a polyfunctional monomer in which the number of hydroxyl group (b) is 3 or more include: trifunctional aromatic compounds such as trihydroxybenzene, trihydroxynaphthalene, trihydroxyanthracene, trihydroxychalcone, trihydroxy flavone, and trihydroxy coumarin; trifunctional aliphatic alcohols such as glycerol, trimethylolpropane, and propanetriol; and tetrafunctional aliphatic alcohols such as pentaerythritol. Any compound obtained by adding a diol to a hydroxy terminal of any of the above-described compound may be preferably used.

One of these compounds may be used singly or two or more thereof may be used in combination as necessary.

Examples of the polyfunctional monomer further includes, other than the above-described monomers, include hydroxy acids which have both a hydroxyl group and a carboxyl group in one molecule, and in which the sum (a+b) of the number of carboxy group (a) and the number of hydroxyl group (b) is three or more. Examples of the hydroxy acid include hydroxyisophthalic acid, hydroxyterephthalic acid, dihydroxyterephthalic acid, and trihydroxyterephthalic acid.

Any one obtained by adding, to any of these polyfunctional monomers, a hydroxy acid such as l-lactide, d-lactide, hydroxybenzoic acid, derivatives thereof, or any in which two or more molecules of the hydroxy acid are connected may also be preferably used.

One of these compounds may be used singly or two or more thereof may be used in combination as necessary.

In raw PET resin in the invention, the content ratio of the above-described constituent unit derived from the polyfunctional monomer in the raw PET resin is preferably from 0.005 mol % to 2.5 mol % with respect to the total constituent units in the raw PET resin. The content ratio of the constituent unit derived from the polyfunctional monomer is more preferably from 0.020 mol % to 1 mol %, more preferably from 0.025 mol % to 1 mol %, even more preferably from 0.035 mol % to 0.5 mol %, particularly preferably from 0.05 mol % to 0.5 mol %, and most preferably from 0.1 mol % to 0.25 mol %.

When the constituent units derived from the polyfunctional monomer having three or more functional groups is present in the raw PET resin, as described above, in the final formation of the PET film, the functional groups which have not been used for polycondensation form a hydrogen bond or a covalent bond with the component in the coating layer (specific coating layer) which has been formed by application to the PET film, so that the adhesion between the coating layer and the PET film can be kept in favorable condition, and the occurrence of peeling can be effectively prevented. In addition, a structure having a branched PET molecular chain is obtained from the constituent units derived from the polyfunctional monomer having three or more functional groups, whereby entanglement between the PET molecules can be promoted.

In the esterification reaction and/or interesterification reaction, any known reaction catalyst may be used. Examples of the reaction catalyst include alkali metal compounds, alkaline earth metal compounds, zinc compounds, lead compounds, manganese compounds, cobalt compounds, aluminum compounds, antimony compounds, titanium compounds, and phosphorus compounds. Usually, it is preferred that an antimony compound, a germanium compound, or a titanium compound be added as a polymerization catalyst in any process before the completion of the production of PET. Taking a germanium compound as an example, it is preferred that a germanium compound powder be added as it is.

For example, the esterification reaction process is carried out by polymerizing an aromatic dicarboxylic acid and an aliphatic diol in the presence of a catalyst containing a titanium compound. In this esterification reaction process, an organic chelate titanium complex having an organic acid ligand as a titanium compound as a catalyst, and the process includes at least a step of adding an organic chelate titanium complex, a magnesium compound, and a pentavalent phosphoric acid ester having no aromatic ring substituent in this order.

Firstly, before the addition of a magnesium compound and a phosphorus compound, an aromatic dicarboxylic acid and an aliphatic diol are mixed with a catalyst containing an organic chelate titanium complex that is a titanium compound. Since the titanium compound such as an organic chelate titanium complex has high catalytic activity for esterification reaction, it is possible to favorably promote esterification reaction. At this time, a titanium compound may be added to the mixture of a dicarboxylic acid component and a diol component, or a diol component (or a dicarboxylic acid component) may be added to the mixture of a dicarboxylic acid component (or a diol component) and a titanium compound. Alternatively, a dicarboxylic acid component, a diol component, and a titanium compound may be mixed together at the same time. The method of mixing is not particularly limited, and the mixing may be carried out a known method.

The PET is more preferably polymerized using one or two or more catalysts selected from the group consisting of germanium (Ge) catalysts, antimony (Sb) catalysts, aluminum (Al) catalysts, and titanium (Ti) catalysts, more preferably using a Ti catalysts.

Since the Ti catalyst has high reaction activity, it is possible to lower the polymerization temperature. As a result of this, pyrolysis of the PET and generation of COOH particularly during the polymerization reaction can be suppressed. More specifically, the use of the Ti catalyst enables the reduction of the amount of terminal carboxylic acid of the PET which can cause pyrolysis, and thus may suppress formation of foreign matter. The reduction of the amount of the terminal carboxylic acid of the PET may also suppress the pyrolysis of the PET film after production of the PET film.

Examples of the Ti catalyst include oxides, hydroxides, alkoxides, carboxylates, carbonates, oxalic acid salts, organic chelate titanium complexes, and halides. With respect to the Ti catalyst, two or more titanium compounds may be used, as long as the effect of the invention will not be impaired.

Examples of the Ti catalyst include titanium alkoxides such as tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, tetrabenzyl titanate; titanium oxide obtained by hydrolysis of titanium alkoxide; titanium-silicon complex oxide or titanium-zirconium complex oxide obtained by hydrolysis of the mixture of titanium alkoxide and silicon alkoxide or zirconium alkoxide; titanium acetate, titanium oxalate, potassium titanium oxalate, sodium titanium oxalate, potassium titanate, sodium titanate, a titanic acid-aluminium hydroxide mixture, titanium chloride, a titanium chloride-aluminum chloride mixture, titanium acetylacetonate, and organic chelate titanium complexes having an organic acid ligand.

In the polymerization of the PET, it is preferable to use a titanium (Ti) compound as a catalyst in an amount of from 1 ppm to 50 ppm, more preferably from 2 ppm to 30 ppm, and even more preferably from 3 ppm to 15 ppm, in terms of titanium element. In this case, the raw PET resin contains from 1 ppm to 50 ppm of titanium element.

In a case in which the amount of titanium element contained in the raw PET resin is 1 ppm or more, the PET has a high weight average molecular weight (Mw), and is resistant to pyrolysis. Accordingly, foreign matter in the extruder decreases. In a case in which the amount of titanium element contained in the raw PET resin is 50 ppm or less, the Ti catalyst is less likely to become foreign matter, whereby stretching unevenness during stretching of the PET sheet is reduced.

[Titanium Compound]

AS the titanium compound that is a catalyst component, at least one organic chelate titanium complex having an organic acid ligand is preferably used. Examples of the organic acid include citric acid, lactic acid, trimellitic acid, and malic acid. Among them, an organic chelate complex having a citric acid ligand or a citrate ligand is preferred.

For example, in a case in which a chelate titanium complex having a citric acid ligand is used, generation of foreign matter such as fine particles is suppressed, whereby a PET having favorable polymerization activity and a favorable color tone is obtained in comparison with the case using other titanium compounds. Further, in a case in which a citric acid chelate titanium complex is used, a PET having favorable polymerization activity, a favorable color tone, and less terminal carboxy groups can be obtained by adding the citric acid chelate titanium complex during esterification reaction, in comparison with the case where the complex is added after esterification reaction. In this regard, it is thought that the titanium catalyst also has catalytic effect on the esterification reaction, and thus decreases the oligomer acid value at the completion of the esterification reaction when added in the esterification process, whereby the following polycondensation reaction more efficiently proceeds. It is also thought that the complex having a citric acid ligand has higher hydrolysis resistance than titanium alkoxide, and is not hydrolyzed during esterification reaction, and effectively functions as a catalyst of esterification and polycondensation reaction while keeping its original activity.

In addition, it is known that hydrolysis resistance usually decreases as the increase of the amount of terminal carboxy groups. It is thus expected that the decrease of the amount of terminal carboxy groups by the above-described addition method would improve hydrolysis resistance.

Examples of the above-described citric acid chelate titanium complex include VERTEC AC-420 manufactured by Johnson Matthey, which is readily commercially available.

The aromatic dicarboxylic acid and aliphatic diol can be introduced by preparing a slurry containing them, and continuously feeding it to the esterification reaction process.

Examples of general titanium compounds other than organic chelate titanium complexes include oxide, hydroxide, alkoxide, carboxylate, carbonate, oxalic acid salts, and halides. The organic chelate titanium complex may be used in combination with another titanium compound, as long as the effect of the invention will not be impaired.

Examples of the titanium compound include tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, tetrabenzyl titanate; titanium oxide obtained by hydrolysis of titanium alkoxide; titanium-silicon complex oxide or titanium-zirconium complex oxide obtained by hydrolysis of the mixture of titanium alkoxide and silicon alkoxide or zirconium alkoxide; titanium acetate, titanium oxalate, potassium titanium oxalate, sodium titanium oxalate, potassium titanate, sodium titanate, a titanic acid-aluminium hydroxide mixture, titanium chloride, a titanium chloride-aluminum chloride mixture, and titanium acetyl acetonate.

In the invention, the PET is preferably produced by the production method including an esterification reaction process which includes at least a process of polymerizing an aromatic dicarboxylic acid with an aliphatic diol in the presence of a catalyst containing a titanium compound, in which at least one of the titanium compound is an organic chelate titanium complex having an organic acid ligand, and which includes adding the organic chelate titanium complex, a magnesium compound, and a pentavalent phosphoric acid ester having no aromatic ring substituent in this order; and a polycondensation process of forming a polycondensate by polycondensation reaction of the esterification reaction product formed by the esterification reaction process.

In this case, the order of addition is such that, during the esterification reaction, a magnesium compound is added to a reaction mixture in which an organic chelate titanium complex that is a titanium compound is present, and then a specific pentavalent phosphorus compound is added. Accordingly, the reaction activity of the titanium catalyst can be kept at an appropriately high level, electrostatic application properties can be imparted by magnesium, and decomposition reaction caused by polycondensation can be effectively suppressed. As a result, the PET to be obtained is less colored, has high electrostatic application properties, and, when exposed to high temperatures, is less yellowed.

Accordingly, it is possible to provide a PET in which coloring during polymerization and coloring during subsequent melt film formation are reduced, and which is less yellowed in comparison with the conventional antimony (Sb) catalyst system PET, has a color tone and transparency equivalent to those of the germanium catalyst system PET having relatively high transparency, and also has high heat resistance. It is also possible to obtain a PET which has high transparency without the use of a color tone controlling agent such as a cobalt compound or a dye, and is less yellowed.

The PET is useful for the applications requiring high transparency (for example, optical film and industrial lithography material), and it is not necessary to use a costly germanium catalyst, which enables a large cost reduction. In addition, inclusion of foreign matter originated from the catalyst, which easily occur in a Sb catalyst system, is prevented, whereby occurrence of defects occurring in film formation and quality defects are reduced, and cost reduction owing to the yield improvement can be achieved.

For the esterification reaction, it is preferable to provide a process of adding an organic chelate titanium complex as a titanium compound, a magnesium compound as an additive, and a pentavalent phosphorus compound as an additive, in this order. At this time, it is possible to progress esterification reaction in the presence of the organic chelate titanium complex, and thereafter, to start the addition the magnesium compound before the addition of the phosphorus compound.

[Phosphorus Compound]

At least one pentavalent phosphoric acid ester having no aromatic ring substituent is used as a pentavalent phosphorus compound. Examples thereof include a phosphoric acid ester [(OR)₃—P═O; R is an alkyl group having 1 or 2 carbon atoms] having a lower alkyl group having 2 or less carbon atoms as a substituent. Specific examples of particularly preferable pentavalent phosphoric acid ester include trimethyl phosphate and triethyl phosphate.

The addition amount of the phosphorus compound is preferably from 50 ppm to 90 ppm in terms of P element. The amount of the phosphorus compound is more preferably from 60 ppm to 80 ppm, and even more preferably from 60 ppm to 75 ppm, in terms of P element.

[Magnesium Compound]

The inclusion of a magnesium compound in the PET improves the electrostatic application properties of PET. In this case, coloring tends to occur. However, in the invention, coloring can be suppressed, and a favorable color tone and high heat resistance can be obtained.

Examples of the magnesium compound include magnesium salts such as magnesium oxide, magnesium hydroxide, magnesium alkoxide, magnesium acetate, and magnesium carbonate. Among them, magnesium acetate is most preferred from the viewpoint of solubility in ethylene glycol.

In order to impart high electrostatic application properties, the addition amount of the magnesium compound is preferably 50 ppm or more, and more preferably from 50 ppm to 100 ppm, in terms of Mg element. The addition amount of the magnesium compound is preferably from 60 ppm to 90 ppm, and even more preferably from 70 ppm to 80 ppm, in terms of Mg element, from the viewpoint of electrostatic application properties.

In the esterification reaction process, it is particularly preferred that the titanium compound as a catalyst component and the magnesium compound and phosphorus compound as additives be added and carry out melt polymerization in such a manner that the value Z calculated from the following formula (i) satisfies the following relational formula (ii). The P content is the amount of phosphorus derived from all the phosphorus compounds including the pentavalent phosphoric acid ester having no aromatic ring, and the Ti content is the amount of titanium derived from all the Ti compounds including the organic chelate titanium complex. In this manner, by selecting the combination of a magnesium compound and a phosphorus compound in the catalyst system containing a titanium compound, and controlling the timing and ratio of addition, a color tone with less yellowing can be obtained while keeping the catalytic activity of the titanium compound at an adequately high level, and heat resistance can be provided such that even when exposed to high temperatures during polymerization reaction and subsequent film formation (melting), yellowing are less likely to occur.

(i) Z=5×(P content [ppm]/P atomic weight)−2×(Mg content [ppm]/Mg atomic weight)−4×(Ti content [ppm]/Ti atomic weight)

(ii) 0≦Z≦+5.0

This is the index which quantitatively expresses the balance between the three compounds, because the phosphorus compound acts on titanium and also interacts with the magnesium compound.

In the above-described formula (i), the amount of phosphorus which can act on titanium is expressed by subtracting the amount of phosphorus acting on magnesium from the total amount of phosphorus available for reaction. When the value Z is positive, the amount of phosphorus inhibiting titanium is excessive, and when the value is negative, the amount of phosphorus necessary for inhibiting titanium is insufficient. In the reaction, since the atoms of Ti, Mg, and P are not equivalent, each of the numbers of moles is multiplied by the valence for weighting.

In the invention, without requiring, for example, a special synthesis, it is possible to obtain a PET having an excellent color tone, high coloring resistance under heat, and sufficient reactivity necessary for reaction, using a titanium compound, a phosphorus compound, and a magnesium compound, which are readily available at low costs.

In the above-described formula (ii), it is preferred to satisfy +1.0≦Z≦+4.0, and more preferred to satisfy +1.5≦Z≦+3.0, from the viewpoint of further improving the color tone and coloring resistance under heat while keeping the polymerization reactivity.

Examples of more preferred embodiments in the invention include an embodiment in which, before completion of the esterification reaction, to the aromatic dicarboxylic acid and the aliphatic diol, a chelate titanium complex having a citric acid or citrate ligand is added in an amount of from 1 ppm to 30 ppm in terms of Ti element, and then a weakly acidic magnesium salt is added in an amount of from 60 ppm to 90 ppm (more preferably from 70 ppm to 80 ppm) in terms of Mg element, in the presence of the chelate titanium complex, and then a pentavalent phosphoric acid ester having no aromatic ring substituent is added in an amount of from 60 ppm to 80 ppm (more preferably from 65 ppm to 75 ppm) in terms of the P element.

In the above-described embodiment, it is preferred that 70% by mass or more of the whole addition amount of each of the chelate titanium complex (organic chelate titanium complex), the magnesium salt (magnesium compound), and the pentavalent phosphoric acid ester be added in the above-described order.

The esterification reaction may be carried out while removing water or alcohol generated by the reaction from the system, using a multistage apparatus composed of at least two reactors connected in series, in the conditions in which ethylene glycol is refluxed.

The above-described esterification reaction may be carried out in one stage or multiple stages.

When the esterification reaction is carried out in one stage, the esterification reaction temperature is preferably from 230 to 260° C., and more preferably from 240 to 250° C.

When the esterification reaction is carried out in multiple stages, the temperature of the esterification reaction in the first reaction vessel is preferably from 230 to 260° C., and more preferably from 240 to 250° C.; the pressure is preferably from 1.0 to 5.0 kg/cm², and more preferably from 2.0 to 3.0 kg/cm². The temperature of the esterification reaction in the second reaction vessel is preferably from 230 to 260° C., and more preferably from 245 to 255° C.; the pressure is preferably from 0.5 to 5.0 kg/cm², and more preferably from 1.0 to 3.0 kg/cm². When the reaction is carried out in three or more stages, the conditions of the esterification reaction in the intermediate stage are preferably the intermediate conditions between the above-described first and final reaction vessels.

—Polycondensation—

In the polycondensation, the esterification reaction product formed by the esterification reaction is subjected to polycondensation reaction, thereby forming a polycondensate. The polycondensation reaction may be carried out in one step or multiple steps.

The esterification reaction product such as an oligomer formed by the esterification reaction is subsequently subjected to polycondensation reaction. The polycondensation reaction is favorably carried out using a multistage polycondensation reaction vessel.

For example, the preferred embodiment of the conditions of the polycondensation reaction in a three-stage reaction vessel are as follows: in the first reaction vessel, the reaction temperature is preferably from 255 to 280° C., and more preferably from 265 to 275° C., the pressure is preferably from 100 to 10 torr (from 13.3×10⁻³ to 1.3×10⁻³ MPa), and more preferably 50 to 20 torr (from 6.67×10⁻³ to 2.67×10⁻³ MPa); in the second reaction vessel, the reaction temperature is preferably from 265 to 285° C., and more preferably 270 to 280° C., the pressure is preferably from 20 to 1 torr (from 2.67×10⁻³ to 1.33×10⁻⁴ MPa), and more preferably from 10 to 3 torr (from 1.33×10⁻³ to 4.0×10⁻⁴ MPa); and in the third reaction vessel in the final reaction vessel, the reaction temperature is preferably from 270 to 290° C., and more preferably from 275 to 285° C., and the pressure is preferably from 10 to 0.1 torr (from 1.33×10⁻³ to 1.33×10⁻⁵ MPa), and more preferably from 5 to 0.5 torr (from 6.67×10⁻⁴ to 6.67×10⁻⁵ MPa).

The PET synthesized as described above may further contains additives such as a light stabilizer, an antioxidant, an ultraviolet absorber, a flame retardant, a lubricant (fine particles), a nucleating agent (crystallizing agent), and a crystallization inhibitor.

The PET as a raw material of the PET sheet is preferably in the form of pellets prepared by solid-state polymerization.

The moisture content, the degree of crystallinity, the acid value (AV) of the PET, more specifically, the concentration of the terminal carboxy group of the PET, and the intrinsic viscosity (IV) of the PET film can be controlled, in a case where solid-state polymerization is carried out after the polymerization by esterification reaction.

In the invention, from the viewpoint of hydrolysis resistance of the PET film, the intrinsic viscosity (IV) of the PET is preferably 0.75 dL/g or more, and more preferably from 0.75 dL/g to 0.9 dL/g. In a case in which the IV is less than 0.75 dL/g, the molecular motion of the PET is not suppressed, so that crystallization readily proceeds. In a case in which the IV is 0.9 dL/g or less, excessive pyrolysis of the PET caused by heat generation due to shearing within the extruder can be suppressed, crystallization cab be suppressed, and the acid value (AV) can be kept low. In particular, the IV is more preferably from 0.75 dL/g to 0.85 dL/g, and more preferably from 0.78 dL/g to 0.85 dL/g.

In particular, crystallization of the PET in the process of cooling of the melt resin in the PET sheet production process is readily suppressed by using a Ti catalyst in the esterification reaction, and by further carrying out a solid-state polymerization to adjust the intrinsic viscosity (IV) of the PET within a range of from 0.75 dL/g to 0.9 dL/g.

Accordingly, the PET as a raw material of the PET film which is to be subjected to vertical stretching and lateral stretching preferably has an intrinsic viscosity of from 0.75 dL/g to 0.9 dL/g, and more preferably further contains a titanium atom derived from the catalyst (Ti catalyst).

The intrinsic viscosity (IV) is obtained by dividing the specific viscosity (ηₛₚ=ηᵣ−1), which is calculated by subtracting 1 from the ratio ηᵣ(=η/η₀; relative viscosity) of the solution viscosity (η) and solvent viscosity (η_{θ}), by the concentration, and extrapolating the value to the zero concentration. The IV is determined by dissolving the PET in 1,1,2,2-tetrachloro ethane/phenol (=⅔ [mass ratio]) mixed solvent, and measuring the solvent viscosity at 25° C. using an Ubbelohde viscometer.

For the solid-state polymerization of the PET, small pieces, such as pellets, of a PET which has been polymerized by the above-described esterification reaction, or a commercially available PET, are used as the starting material.

The solid-state polymerization of PET may be carried out by a continuous process (a method in which a resin is packed in a tower, is retained and flows slowly under heating for a predetermined time, and then is sent out successively), or a batch process (a resin is charged into a container, and heated for a predetermined time).

The solid-state polymerization is preferably carried out in vacuo or in a nitrogen atmosphere.

The solid-state polymerization temperature for the PET is preferably from 150° C. to 250° C., more preferably from 170° C. to 240° C., and even more preferably from 180° C. to 230° C. The temperature within the above-described range is preferable in that the acid value (AV) of the PET is further reduced.

The solid-state polymerization time is preferably from 1 hour to 100 hours, more preferably from 5 hours to 100 hours, even more preferably from 10 hours to 75 hours, and particularly preferably from 15 hours to 50 hours. In a case in which the solid-state polymerization time is within the above-described range, the acid value (AV) and intrinsic viscosity (IV) of the PET can be readily controlled to within the preferable range.

The temperature of the solid-state polymerization is preferably from 170° C. to 240° C., more preferably from 180° C. to 230° C., and even more preferably from 190° C. to 220° C.

(Melt Extrusion)

In film forming process in the invention, the raw PET resin obtained as described above is melt-extruded, and further cooled to form a PET film.

The melt extrusion of the raw PET resin is, for example, carried out, using an extruder having one or more screws, while heating the raw PET resin to a temperature higher than the melting point, and melt-kneading by the rotating screw. The raw PET resin is molten to be a melt by heating and kneading by the screw in the extruder. In order to suppress pyrolysis (hydrolysis of the PET) in the extruder, the inside of the extruder is preferably purged with nitrogen and the melt extrusion of the raw PET resin is carried out. The extruder is preferably a twin screw extruder for keeping the kneading temperature low.

The molten raw PET resin (melt) is extruded from an extrusion die through, for example, a gear pump and a filter. The extrusion die may be referred to simply as “die” [see JIS B 8650: 2006, a) Extruder, No. 134].

The melt may be extruded in a single layer or multiple layers.

The raw PET resin preferably contains a terminal blocking agent selected from an oxazoline compound, a carbodiimide compound, or an epoxy compound. In this case, in the film forming process, the raw PET resin containing the terminal blocking agent is melt-kneaded, and the raw PET resin which has been reacted with the terminal blocking agent during melt kneading is melt-extruded.

In a case where the process of adding the terminal blocking agent to the raw PET resin is provided, weather resistance can improved, and heat shrinkage can be controlled to a low level. In addition, when the PET film is formed, the terminal blocking agent is bonded to the PET terminal to bulk up the terminal parts of the chain, and increases the fine concavities and convexities on the film surface, whereby the anchoring effect is readily developed, and the adhesion between the PET film and the coating layer formed on the film is improved.

The time point of adding the terminal blocking agent is not particularly limited, as long as the terminal blocking agent is melt-kneaded together with the raw PET resin during the course from the addition of the raw material to extrusion. It is preferred that the terminal blocking agent be added after the raw material is charged into the cylinder and before the raw material is sent by a screw to the vent, and subjected to melt kneading together with the raw material resin. For example, a feeding port for feeding the terminal blocking agent may be provided between the raw material inlet and the vent of the cylinder in which melt kneading is carried out, and the terminal blocking agent may be added directly to the raw material resin in the cylinder. In this case, the terminal blocking agent may be added to the raw PET resin which is under heating kneading but is not completely molten, or to the raw PET resin in a molten state (melt).

The amount of the terminal blocking agent to the raw PET resin is preferably from 0.1% by mass to 5% by mass with respect to the total mass of the raw PET resin. The amount of the terminal blocking agent to the raw PET resin is preferably from 0.3% by mass to 4% by mass, and even more preferably from 0.5% by mass to 2% by mass.

When the proportion of the terminal blocking agent is 0.1% by mass or more, improvement of weather resistance due to the AV decrease effect can be achieved, and low heat shrinkability and excellent adhesion can be imparted. When the content ratio of the terminal blocking agent is 5% by mass or less, adhesion can be improved, and decrease of the glass transition temperature (Tg) of the PET due to the addition of the terminal blocking agent can be suppressed, whereby the decrease in weather resistance and increase in heat shrinkage due to the decrease of Tg can be suppressed. The reason for this is that the increase in hydrolyzability due to the increase of reactivity of the PET occurring relative to the decrease in Tg is suppressed, and heat shrinkage caused by the increase in mobility of the PET molecules due to the Tg decrease is suppressed.

The terminal blocking agent in the invention is preferably a compound having a carbodiimide group, an epoxy group, or an oxazoline group. Specific examples of the preferred terminal blocking agent include a carbodiimide compound, an epoxy compound, and an oxazoline compound.

Examples and the details such as a preferred embodiment of the carbodiimide compound, epoxy compound, and oxazoline compound are as described in the above-described section of “PET film”.

The melt is extruded from the die onto the casting drum, thereby forming a film by cast treatment.

The thickness of the PET formed product in a film form obtained by cast treatment is preferably from 0.5 mm to 5 mm, more preferably from 0.7 mm to 4.7 mm, and even more preferably from 0.8 mm to 4.6 mm.

In a case where the thickness of the PET formed product in a film form is 5 mm or less, delay in cooling caused by heat accumulation in the melt is avoided, and in a case where the thickness is 0.5 mm or more, OH groups and COOH groups in the PET are diffused within the PET during the time from the extrusion to cooling, whereby the exposure of the OH groups and COOH groups from the PET surface, which can cause hydrolysis, is suppressed.

The means or device for cooling the melt extruded from the extrusion die is not particularly limited. The melt may be exposed to cold air, contacted with a cast drum (cooling cast drum), or sprayed with water. One cooling means or device may be used singly or two or more thereof may be used in combination.

Among the above cooling means or device, from the viewpoint of preventing adhesion of oligomer to the sheet surface during continuous operation, at least one of cooling by cold air or cooling using a cast drum is preferred. It is particularly preferred that the melt extruded from the extruder be cooled by cold air, and contacted with the cast drum thereby cooling the melt.

The PET formed product which has been cooled using a cast drum or the like is peeled from a cooling member such as a cast drum or the like, using a peeling member such as a peeling roll.

[Vertical Stretching Process]

In the vertical stretching process in the invention, the PET film formed in the above-described film forming process is vertically stretched in a longitudinal direction.

The vertical stretching of the film may be carried out by, for example, passing the film between a pair of nip rolls sandwiching the film, and applying a tension to the film by two or more pairs of nip rolls arranged in the machine direction of the film, while conveying the film in the longitudinal direction of the film. Specifically, for example, in a case where a pair of nip rolls A are arranged at the upstream side of the machine direction of the film and a pair of nip rolls B are arranged at the downstream side of the machine direction of the film, the film is stretched in the conveying direction (MD) by setting the rotation speed of the nip rolls B at the downstream side faster than the rotation speed of the nip rolls A at the upstream side during transportation of the film. Two or more pairs of nip rolls may be installed independently at each of the upstream side and the downstream side. For the vertical stretching of the PET film, a vertical stretching apparatus equipped with the above-described nip rolls may be used.

In the vertical stretching process, the vertical stretching ratio of the PET film is preferably from 2 to 5 times, more preferably from 2.5 to 4.5 times, and even more preferably from 2.8 to 4 times.

The area stretching ratio expressed by the product of the vertical stretching ratio and the horizontal stretching ratio is preferably from 6 times to 18 times, more preferably from 8 times to 17.5 times, and even more preferably from 10 times to 17 times the area of the PET film before stretching.

The vertical temperature of the PET film during stretching (hereinafter may be referred to as “vertical stretching temperature”) is preferably from Tg−20° C. to Tg+50° C., more preferably from Tg−10° C. to Tg+40° C., and even more preferably from Tg to Tg+30° C., wherein Tg represents the glass transition temperature of the PET film.

As the means or device for heating the PET film, in a case in which the film is stretched using rolls such as nip rolls, the PET film in contact with the rolls can be heated by providing a heater or a pipe for conveying a warm solvent in the rolls. In a case in which no roll is used, the PET film can be heated by blowing warm air to the PET film, bringing the PET film into contacted with or passing the PET film near a heat source such as a heater.

The method for producing the PET film of the invention includes the below-described lateral stretching process, in addition to the vertical stretching process. Therefore, in the method for producing the PET film of the invention, the PET film is stretched at least in two directions, or the longitudinal direction of the PET film (conveying direction, MD) and the direction (TD) orthogonal to the longitudinal direction of the PET film. Stretching in the MD direction and the TD direction may be carried out at least once in each direction.

The term “the direction (TD) orthogonal to the longitudinal direction (conveying direction, MD) of the PET film” means the direction perpendicular)(90° to the longitudinal direction (conveying direction, MD) of the PET film, and includes in its scope the direction which can be regarded as a direction at an angle of substantially 90° (for example, a direction at 90°±5° to the MD direction) to the longitudinal direction (or the machine direction) in view of, for example, a mechanical error.

The method of biaxially stretching may be sequential biaxially stretching wherein vertical stretching and lateral stretching are carried out independently, or simultaneous biaxially stretching wherein vertical stretching and lateral stretching are carried out simultaneously. Each of the vertical stretching and the lateral stretching may be independently carried out twice or more. The vertical stretching and the lateral stretching may be carried out in any order. Examples of the embodiment of stretching include vertical stretching→lateral stretching, vertical stretching→lateral stretching→vertical stretching, vertical stretching→vertical stretching→lateral stretching, and lateral stretching→vertical stretching. Among them, vertical stretching→lateral stretching is preferred.

[Lateral Stretching Process]

The lateral stretching process in the invention is described below in detail.

The lateral stretching process in the invention is a process of laterally stretching the vertically stretched PET film in the width direction orthogonal to the longitudinal direction. The lateral stretching process includes a preheating process of preheating the vertically stretched PET film to a temperature at which the film can be stretched, a stretching process of laterally stretching the preheated PET film by applying a tension to the film in the width direction orthogonal to the longitudinal direction, a heat setting process of heat-setting the vertically and laterally stretched PET film by heating in such a manner that the maximum film surface temperature is in the range of from 160° C. to 225° C., a heat relaxation process of heating the heat-set PET film thereby relaxing the tension on the PET film, and a cooling process of cooling the PET film after the heat relaxation.

For the lateral stretching process in the invention, the specific means or device used therefor is not particularly limited as long as the PET film is laterally stretched in the above-described constitution, but a lateral stretching apparatus or biaxial stretching machine capable of performing the treatment of the processes of the above-described constitution is preferably used.

—Biaxial Stretching Machine—

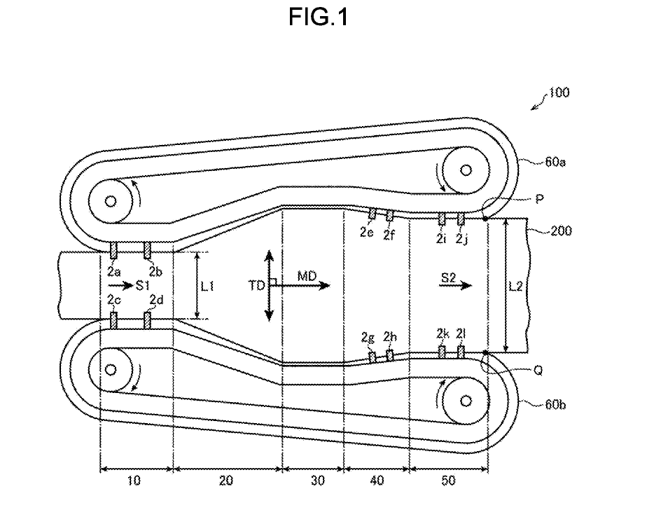

As shown in FIG. 1, the biaxial stretching machine 100 includes a pair of cyclic rails 60a and 60b, and holding members 2a to 2l which are installed on the cyclic rails, and movable along the rails. The cyclic rails 60a and 60b are symmetrically arranged with the PET film 200 sandwiched therebetween, and the holding members 2a to 2l hold the PET film 200, and are capable of stretching the PET film in the film width direction by moving along the rails.

FIG. 1 is a top view of an example of the biaxial stretching machine.

The biaxial stretching machine 100 is configured with the regions including a preheating part 10 for preheating the PET film 200, a stretching part 20 for stretching the PET film 200 in the TD direction marked with arrows, which is a direction orthogonal to the MD direction marked with an arrow, to apply a tension to the PET film, a heat setting part 30 for heating the tensed PET film under tension, a heat relaxation part 40 for heating the heat-set PET film to relax the tension on the heat-set PET film, and a cooling part 50 for cooling the PET film which passed the heat relaxation part.

Holding members 2a, 2b, 2e, 2f, 2i, and 2j which are movable along the cyclic rail 60a are mounted on the cyclic rail 60a, and holding members 2c, 2d, 2g, 2h, 2k, and 2l which are movable along the cyclic rail 60b are mounted on the cyclic rail 60b. The holding members 2a, 2b, 2e, 2f, 2i, and 2j each hold an end portion of one end of the PET film 200 in the TD direction, and the holding members 2c, 2d, 2g, 2h, 2k, and 2l each hold an end portion of the other end of the PET film 200 in the TD direction. The holding members 2a to 2l are commonly referred to as, for example, chucks or clips. The holding members 2a, 2b, 2e, 2f, 2i, and 2j move counterclockwise along the cyclic rail 60a, and the holding members 2c, 2d, 2g, 2h, 2k, and 2l move clockwise along the cyclic rail 60b.

The holding members 2a to 2d hold an end portion of the PET film 200 in the preheating part 10, move along the cyclic rail 60a or 60b while holding the PET film 200, pass through the stretching part 20 and the heat relaxation part 40 in which the holding members 2e to 2h are located, and proceeds to the cooling part 50 in which the holding members 2i to 2l are located. Subsequently, the holding members 2a and 2b, and the holding members 2c and 2d each release the end portion of the PET film 200 in the order of the conveying direction at the downstream end of the cooling part 50 in the MD direction, and further move along the cyclic rail 60a or 60b, and return to the preheating part 10. At this time, the PET film 200 moves in the MD direction marked with an arrow, and is successively subjected to the preheating process in the preheating part 10, the stretching process in the stretching part 20, the heat setting process in the heat setting part 30, the heat relaxation process in the heat relaxation part 40, and the cooling process in the cooling part 50, and the lateral stretching is carried out. The moving speed of the holding members 2a to 2l in each region such as a preheating part is the conveying speed of the PET film 200.

The moving speeds of the holding members 2a to 2l can be changed independently.

The biaxial stretching machine 100 can laterally stretch the PET film 200 in the TD direction in the stretching part 20, and also can stretch the PET film 200 in the MD direction by changing the moving speed of the holding members 2a to 2l. More specifically, simultaneous biaxially stretching can be carried out using the biaxial stretching machine 100.

In FIG. 1, only the holding members 2a to 2l are shown as the members each holding an end portion of the PET film 200 in the TD direction, but the biaxial stretching machine 100 has other unshown holding members besides the holding members 2a to 2l for supporting the PET film 200. The holding members 2a to 2l may be hereinafter referred to generally as “holding members 2.”

(Preheating Process)

In the preheating process, the PET film which has been vertically stretched in the above-described vertical stretching process is preheated to the temperature at which the film is stretchable.

As shown in FIG. 1, the PET film 200 is preheated in the preheating part 10. In the preheating part 10, the PET film 200 is preheated before stretching, thereby facilitating the lateral stretching of the PET film 200.

The film surface temperature at the endpoint of the preheating part (hereinafter may be referred to as “preheated temperature”) is preferably from Tg−10° C. to Tg+60° C., and more preferably from Tg° C. to Tg+50° C., wherein Tg is the glass transition temperature of the PET film 200.

The endpoint of the preheating part is the endpoint of preheating of the PET film 200, more specifically the position at which the PET film 200 leaves the region of the preheating part 10.

(Stretching Process)

In the stretching process, tension is applied to the PET film which has been preheated in the above-described preheating process is laterally stretched by application of tension in the width direction (TD direction) orthogonal to the longitudinal direction (MD direction) and.

As shown in FIG. 1, in the stretching part 20, the preheated PET film 200 is at least laterally stretched in the TD direction orthogonal to the longitudinal direction of the PET film 200, thereby applying tension the PET film 200.

In the stretching part 20, the tension for lateral stretching (stretching tension) applied to the PET film 200 is preferably from 0.1 t/m to 6.0 t/m.

The area stretching ratio (the product of the stretching ratios) of the PET film 200 is preferably from 6 times to 18 times, more preferably from 8 times to 17.5 times, and even more preferably from 10 times to 17 times the area of the PET film 200 before stretching.

The film surface temperature of the PET film 200 during lateral stretching (hereinafter may be referred to as “lateral stretching temperature”) is preferably from Tg−10° C. to Tg+100° C., more preferably from Tg° C. to Tg+90° C., and even more preferably from Tg+10° C. to Tg+80° C., wherein Tg represents the glass transition temperature of the PET film 200.

As described above, the moving speeds of the holding members 2a to 2l can be changed independently. Accordingly, for example, the PET film 200 can be also vertically stretched in the conveying direction (MD direction) by increasing the moving speed of the holding member 2 at the MD direction downstream side of the stretching part 20, such as the stretching part 20 and heat setting part 30, to exceed the moving speed of the holding member 2 in the preheating part 10. The vertical stretching of the PET film 200 in the lateral stretching process may be carried out in the stretching part 20 alone, or in the below-described heat setting part 30, heat relaxation part 40, or cooling part 50. The vertical stretching may be carried out in plural points.

(Heat Setting Process)

In the heat setting process, the PET film which has been subjected to vertical stretching and lateral stretching is heat-set by heating in such a manner that the maximum film surface temperature is from 160° C. to 225° C.

The heat setting means that the PET film 200 is heated in the stretching part 20 under tension at a specific temperature to cause crystallization.

In the heat setting part 30 shown in FIG. 1, the tensed PET film 200 is heated in such a manner that the maximum film surface temperature of the PET film 200 (may be referred herein as “heat setting temperature”) is controlled to be within the range from 160° C. to 225° C. In a case where the maximum film surface temperature is lower than 160° C., the PET is hardly crystallized, so that the PET molecules cannot be set in an extended state, and thus hydrolysis resistance cannot be improved. On the other hand, in a case where the heat setting temperature is higher than 225° C., slipping occurs at a portion where PET molecules are entangled, and the PET molecules shrink, so that hydrolysis resistance cannot be improved. In other words, in a case where the maximum film surface temperature is from 160° C. to 225° C., the crystals of the PET molecules can be oriented, whereby hydrolysis resistance can be improved.

The heat setting temperature is preferably from 205° C. to 225° C., from the same reason as above.

The maximum film surface temperature (heat setting temperature) is measured by contacting a thermocouple with the surface of the PET film 200.

The heating of the film during heat setting may be carried out from one side or both sides of the film. For example, when the film is cooled on a casting drum after melt extrusion in the above-described film forming process, the degree of cooling of the formed PET film on one side is different from the opposite side, so that the film tends to curl. Therefore, it is preferred that the heating in the main heat setting process be carried for the side which has been contacted with the casting drum in the film forming process. In the heat setting process, curling can be overcome by heating the side which has been contacted with the casting drum, or cooled surface.

The heating is preferably carried out in such a manner that the surface temperature of the heated side immediately after heating in the heat setting process is higher than the surface temperature of the unheated side that is the opposite side to the heated side, by 0.5° C. to 5.0° C. In a case where the temperature of the heated side during heat setting is higher than the temperature of the unheated side that is the opposite side, and the temperature difference between these sides is from 0.5 to 5.0° C., curling of the film is more effectively overcome. From the viewpoint of overcoming curling, the temperature difference between the heated side and the unheated side on the opposite side is more preferably from 0.7 to 3.0° C., and even more preferably from 0.8° C. to 2.0° C.

In a case in which heat setting is carried out as described above, the effect of overcoming curling enhances when the thickness of the PET film is from 180 μm to 350 μm. In a case in which the film has a large thickness, if temperature change is given to the film from one side, temperature distribution tends to be formed in the film thickness direction, and curling tends to occur. For example, when the melt-extruded PET is contacted with the cast drum in the film forming process, the PET is cooled from one side, and the opposite side dissipates heat upon contact with, for example, the atmosphere. However these two sides are cooled in a manner different from each other, so that a temperature difference tends to arise. Accordingly, in a case in which the thickness of the PET film is 180 μm or more, a temperature difference tends to arise, the effect of overcoming curling can be expected. The thickness of 350 μm or less is advantageous since hydrolysis resistance may be favorably maintained.

In the film, the temperature of the end portions in the width direction orthogonal to the longitudinal direction decrease since, for example, clips or the like are attached as described above. Therefore, it is preferred that the end portions of the PET film in the width direction be heated during heat setting. In particular, radiation heating using a radiation heater such as an infrared heater is more preferred.

When the film is heated in the heat setting process, the residence time in the heat setting part is preferably from 5 seconds to 50 seconds. The residence time is the period during which the film is heated within the heat setting part. The residence time of 5 seconds or more is advantageous since the change of degree of crystallinity to the heating time decreases, so that the variation in the degree of crystallinity in the width direction is relatively less likely to occur. The residence time of 50 seconds or less is advantageous in productivity, since there is no need of extremely decrease the line rate of the tenter.

In particular, the residence time is preferably from 8 seconds to 40 seconds, and more preferably from 10 seconds to 30 seconds, from the same reason as described above.

In the invention, in addition to the heat setting process, the end portions of the PET film in the width direction may be further subjected to radiational heating using a radiation heater such as an infrared heater in at least one of the preheating process, the stretching process, and the heat relaxation process

(Heat Relaxation Process)

In the heat relaxation process, the PET film which has been set in the above-described heat setting process is heated, thereby relaxing the tension on the PET film, and removing residual strain. As a result of this, dimensional stability of the film is improved. Further, hydrolysis resistance is also achieved when the IV value of the PET film thus obtained is 0.75 or more.

In a preferred embodiment, in the heat relaxation part 40 shown in FIG. 1, the PET film 200 is heated in such a manner that the maximum film surface temperature of the PET film 200 is lower by 5° C. or more than the maximum film surface temperature (T_{heat setting}) of the PET film 200 in the heat setting part 30.

Hereinafter, the maximum film surface temperature of the PET film 200 during heat relaxation may be referred to as “heat relaxation temperature (T_{heat relaxation})”.

In the heat relaxation part 40, tension is eased (stretching tension is eased) by heating with the heat relaxation temperature (T_{heat relaxation}) lower than the heat setting temperature (T_{heat setting}) by 5° C. or more (T_{heat relaxation}≦T_{heat setting}−5° C.), whereby the dimensional stability of the PET film can be further improved.

In a case where the T_{heat relaxation} is “T_{heat setting}−5° C.” or less, the PET film has further excellent hydrolysis resistance. T_{heat relaxation} is preferably 100° C. or higher, in view of achieving favorable dimensional stability.

It is preferable that T_{heat relaxation} is in the range of 100° C. or higher, and lower than T_{heat setting} by 15° C. or more (100° C.≦T_{heat relaxation}≦T_{heat setting}−15° C.), it is more preferable that T_{heat relaxation} is in the range of 110° C. or higher and lower than T_{heat setting} by 25° C. or more (110° C.≦T_{heat relaxation}≦T_{heat setting}−25° C.), and it is particularly preferable that T_{heat relaxation} is in the range of 120° C. or higher and lower than T_{heat setting} by 30° C. or more (120° C.≦T_{heat relaxation}≦T_{heat setting}−30° C.).

The T_{heat relaxation} is the value measured by contacting a thermocouple to the surface of the PET film 200.

In the heat relaxation part 40, the PET film 200 is relaxed at least in the TD direction. As a result of this treatment, the tensed PET film 200 is shrunk in the TD direction. In the relaxation in the TD direction, the stretching tension applied to the PET film 200 in the stretching part 20 is weakened by 2% to 90%, preferably 40% in the invention.

(Cooling Process)

In the cooling process, the PET film after subjecting to heat relaxation in the above-described heat relaxation process is cooled.

As shown in FIG. 1, in the cooling part 50, the PET film 200 after passing through the heat relaxation part 40 is cooled. The shape of the PET film 200 is fixed by cooling the PET film 200 which has been heated in the heat setting part 30 and the heat relaxation part 40.

The film surface temperature of the PET film 200 at the cooling part outlet of the cooling part 50 (hereinafter may be referred to as “cooling temperature”) is preferably lower than the glass transition temperature Tg of the PET film 200+50° C. Specifically, the temperature is preferably from 25° C. to 110° C., more preferably from 25° C. to 95° C., and even more preferably from 25° C. to 80° C. When the cooling temperature is within this range, uneven shrinkage of the film occurring after releasing can be prevented.

The cooling part outlet means the end of the cooling part 50 when the PET film 200 leaves the cooling part 50, and the position where the holding member 2 holding the PET film 200 (the holding members 2j and 2l in FIG. 1) release the PET film 200.

In the preheating, the stretching, the heat setting, the heat relaxation, and the cooling in the lateral stretching process, the temperature control means or device for heating or cooling the PET film 200 may be, for example, blowing warm air or cold air on the PET film 200, contacting the PET film 200 with the surface of a metal plate whose temperature can be controlled, or passing the PET film 200 in the vicinity of the metal plate.

(Collection of Film)

The PET film 200 cooled in the cooling process is cut at the holding parts held by the clips at the both ends in the TD direction, and wound into a roll.

In the lateral stretching process, the stretched PET film is preferably relaxed by the following method, in order to further improve the hydrolysis resistance and dimensional stability of the PET film produced.

In the invention, after carrying out the lateral stretching process after the vertical stretching process, relaxation in the MD direction is preferably carried out in the cooling part 50.

More specifically, in the preheating part 20, the both ends of the PET film 200 in the width direction (TD) are held using at least two holding members for each end. For example, one end of the PET film 200 in the width direction (TD) is held by holding members 2a and 2b, and the other end is held by holding members 2c and 2d. Subsequently, by moving the holding members 2a to 2d, the PET film 200 is conveyed from the preheating part 20 to the cooling part 50.

In the conveying, by narrowing the distance between the holding member 2a (2c) holding one end of the PET film 200 in the width direction (TD direction) and the other holding member 2b (2d) adjacent to the holding member 2a (2c) in the preheating part 20 than the distance between the holding member 2a (2c) holding one end of the PET film 200 in the width direction and the other holding member 2b (2d) adjacent to the holding member 2a (2c) in the cooling part 50, the conveying speed of the PET film 200 is decreased. Using this method, relaxation in the MD direction in the cooling part 50 can be performed.

The relaxation of the PET film 200 in the MD direction may be carried out in at least a portion of the heat setting part 30, the heat relaxation part 40, or the cooling part 50.

As described above, by narrowing the distance between the holding members 2a and 2b and the distance between the holding members 2c and 2d in the downstream region in comparison with the upstream region in the MD direction, relaxation of the PET film 200 in the MD direction can be performed. Accordingly, in order to perform relaxation in the MD direction in the heat setting part 30 or heat relaxation part 40, the moving speed of the holding members 2a to 2d may be decreased when the holding members 2a to 2d arrive the heat setting part 30 or the heat relaxation part 40 to decrease the conveying speed of the PET film 200, and to narrow the distance between the holding members 2a and 2b, and the distance between the holding members 2c and 2d, in comparison with the distance in the preheating part.

In this manner, in the lateral stretching process, by subjecting the PET film 200 to stretching (lateral stretching) and relaxation in the TD direction, and also stretching (vertical stretching) and relaxation in the MD direction, dimensional stability can be improved while hydrolysis resistance can be improved.

<Method for Producing Solar Cell Backsheet>

The method for producing a solar cell backsheet of the invention includes a first layer formation process of applying a first layer-forming coating liquid containing at least a binder containing an acrylic resin, a carbodiimide crosslinking agent, and inorganic fine particles to at least one side of a substrate which is a biaxially stretched polyethylene terephthalate film having a pre-peak temperature of 160° C. to 225° C. as measured by differential scanning calorimetry (DSC), thereby forming a first layer by application, and a second layer formation process of forming a second layer containing a resin binder as a main component on the first layer.

In the method for producing a solar cell backsheet of the invention, the first layer corresponds to the above-described specific coating layer, and the second layer corresponds to the above-described adhesive layer.

The second layer formation process may be a sheet-like member lamination process of laminating an adhesive sheet-like member containing a resin binder as a main component to the above-described first layer thereby forming the second layer, or an application process of applying a coating liquid containing a resin binder as a main component to the above-described first layer thereby forming the second layer by application.

Details about the coating liquid used in the first layer formation process, more specifically the coating liquid for forming the specific coating layer and the application method are as described above. Before applying the coating liquid to the substrate of the invention, the surface of the substrate may be subjected to surface treatment such as acid etching treatment with a mixture of sulfuric acid and chromic acid, flame treatment with a gas flame, ultraviolet irradiation treatment, corona discharge treatment, or glow discharge treatment.

Details about the easy adhesive sheet-like member and the method for bonding the easy adhesive sheet-like member used in the second layer formation process, and details about the coating liquid for forming the adhesive layer and the application method are also described above.

<Solar Cell Module>

In general, solar cell modules have a configuration in which a solar cell element which converts light energy of sunlight into electrical energy is sandwiched between a transparent substrate into which sunlight enters, and the above-described polyester film (solar cell backsheet) of the invention. In an specific embodiment, solar cell module may have a configuration in which an electric generating element (solar cell element) connected to a lead wiring (not shown) for withdrawing electricity is sealed with a sealant such as an ethylene-vinyl acetate copolymer (EVA) resin, the resulting product is sandwiched between a transparent substrate such as glass and the polyester film (backsheet) of the invention, and these components are bonded together.

As the solar cell element, any of various known solar cell elements may be used, examples thereof include silicon system elements such as single crystal silicon, polycrystalline silicon, or amorphous silicon system element, and group III-V or II-VI compound semiconductor system elements such as copper-indium-gallium-selenium, copper-indium-selenium, cadmium-tellurium, or gallium-arsenic system element. The space between the substrate and polyester film may be sealed with, for example, a resin (so-called sealer) such as an ethylene-vinylacetate copolymer.

### EXAMPLES

The invention is further specifically described below with reference to examples, but the invention is limited to the following examples as long as the gist of the invention is retained. Unless otherwise noted, “part” and “%” are based on mass.

<Intrinsic Viscosity (IV) of PET and Acid Value (AV) of PET>

The intrinsic viscosity (IV) and acid value (AV) of the PET (raw material or substrate) used in the examples and comparative examples were determined as follows.

The intrinsic viscosity (IV) was determined by dissolving the PET in a 1,1,2,2-tetrachloro ethane/phenol (=⅔ [mass ratio]) mixed solvent, and measuring the solution viscosity in the mixed solvent at 25° C.

The acid value (AV) was determined by completely dissolving the PET in a benzyl alcohol/chloroform (=⅔; volume ratio) mixed solution, titrating the solution with a standard solution (0.025 N KOH-methanol mixed solution) using phenol red as the indicator, and calculating the acid value from the amount used for the titration.

### Example 1

### Production of Substrate

The substrate for the substrate film of the solar cell backsheet was produced by the following procedure.

Firstly, polyethylene terephthalate (PET) having an intrinsic viscosity of 0.66 obtained through polycondensation using Ti as a catalyst was dried to a moisture content of 50 ppm or less, and the thus obtained material was used as a PET raw material (PET raw material 1). The moisture content of the PET was measured at 25° C. using a micro moisture meter (Karl Fischer's method).

The PET raw material 1 thus obtained was fed into an extruder in which a heater temperature was adjusted to 280° C. to 300° C., and melt-kneaded in the extruder.

The melt resin was ejected from the die onto a chill roll (cooling roll) which had been electrostatically charged, thereby obtaining an unstretched film (amorphous base). The amorphous base thus obtained was stretched (vertically) in the conveying direction (MD) of the amorphous base. Subsequently, the base was stretched (laterally) in the width direction (TD) orthogonal to the MD, heat-set at 225° C., thereby obtaining a PET substrate 1 having a thickness of 125 μm.

The thickness of the PET substrate 1 was obtained as follows.

Using a contact film thickness meter (manufactured by Anritsu Company), fifty points were sampled over a length of 0.5 m on the PET substrate 1 at regular intervals in the vertically stretched direction (longitudinal direction of the PET substrate 1), and additional fifty points were sampled at regular intervals (divided into 50 equal parts in the width direction) over the total width of the PET substrate 1 in the film width direction (the direction orthogonal to the longitudinal direction). Thereafter, the thickness of these 100 points were measured. The average thickness of these 100 points was determined, and is defined as the thickness of the PET substrate 1.

(Formation of Coating Layer and Adhesive Layer)

The PET substrate 1 thus obtained was conveyed at a conveying speed of 105 m/minute, and the both sides of the PET substrate 1 were subjected to corona discharge treatment at 730 J/m².

—Formation of First Layer (Coating Layer)—

The following first layer coating liquid (1) was applied by bar coating to one side of the PET substrate 1 which had been subjected to corona discharge treatment, to give a dry mass of 233 mg/m², thereby obtaining a coating film 1. Thereafter, the coating film 1 was dried at 180° C. for 1 minute to form a first layer.

—Preparation of the First Layer Coating Liquid (1)—

| | |
|---|---|
| Polyacryl binder (binder) | 19.1 parts |
| [JULIMER ET-410 (trade name), manufactured | |
| by Toagosei Co., Ltd., solid content 30%] | |
| Carbodiimide compound (carbodiimide | 9.0 parts |
| crosslinking agent) | |
| [CARBODILITE V-02-L2 (trade name), | |
| manufactured by Nisshinbo Chemical Inc., solid | |
| content 20%] | |
| Surfactant A | 15.0 parts |
| [1% aqueous solution of NAROACTY CL-95 | |
| (trade name), manufactured by Sanyo Chemical | |
| Industries, Ltd.] | |
| Inorganic filler (inorganic fine particle) | 73.0 parts |
| [TDL-1 (trade name), manufactured by Mitsubishi | |
| Materials Electronic Chemicals Co., Ltd., | |
| 17% aqueous solution of tin oxide] | |
| Distilled water | An amount to make the |
| | total amount 1,000 parts |

The above-described ingredients were mixed to prepare the first layer coating liquid (1) for forming the first layer.

—Formation of Second Layer (Adhesive Layer)—

The following second layer coating liquid (1) was applied by bar coating to the first layer obtained above, so as to give a dry weight of 65.9 mg/m², thereby forming a coating film 2. Thereafter, the coating film 2 was dried at 170° C. for 1 minute to form a second layer.

—Preparation of Second Layer Coating Liquid (1)—

| | |
|---|---|
| Polyacryl binder (resin binder) | 21.0 parts |
| [JULIMER ET-410 (trade name), manufactured | |
| by Toagosei Co., Ltd., solid content 30%] | |
| Epoxy compound | 221.8 parts |
| [DENACOL EX-614B (trade name), manufactured | |
| by Nagase ChemteX Corporation, solid content 1%] | |
| Surfactant A | 25.0 parts |
| [1% aqueous solution of NAROACTY CL-95 | |
| (trade name), manufactured by Sanyo | |
| Chemical Industries, Ltd.] | |
| Distilled water | An amount to make the |
| | total amount 1,000 parts |

The above-described ingredients were mixed to prepare the second layer coating liquid (1) for forming the second layer.

As described above, a solar cell backsheet 1 in which the first layer (coating layer) and the second layer (adhesive layer) are disposed one another in layers in this order on one side of the PET substrate 1 was obtained.

Table 1 shows the ingredients of the first layer and the second layer. In the column of “First layer (coating layer)”, the amounts of the crosslinking agent and fine particles [%] are the mass ratios with respect to the mass of the total solid content in the layer.

<Evaluation of Solar Cell Backsheet>

—Weather Resistance Evaluation (Breaking Stress, Elongation at Break)—

The solar cell backsheet 1 was measured for the breaking stress and the elongation at break before and after the acceleration test (acceleration test 1) wherein the sheet was allowed to stand for 48 hours at 120° C. and 100% RH. The breaking stress and the elongation at break were measured as follows: the solar cell backsheet 1 was subjected to tensile test using a Tensilon universal testing machine (STROGRAPH VE50 (trade name), manufactured by Toyo Seiki Co., Ltd.) in accordance with the method described in JIS-K7127, and the stress and elongation at the broken point were determined.

The retention ratio of elongation at break was calculated by the following formula (L), wherein L_{before} is the elongation at break of the solar cell backsheet 1 before the acceleration test 1, and L_{after} is the elongation at break of the solar cell backsheet 1 after the acceleration test 1.

Retention ratio [%] of elongation at break=(L_{after}/L_{before})×100 Formula (L)

In addition, the retention ratio of breaking stress was calculated by the following formula (N), wherein N_{before} is the breaking stress of the solar cell backsheet 1 before the acceleration test 1, and N_{after} is the breaking stress of the solar cell backsheet 1 after the acceleration test 1.

Breaking stress retention ratio [%]=(N_{after}/N_{before})×100 Formula (N)

On the basis of the retention ratio elongation at break and the retention ratio of breaking stress thus calculated, weather resistance was evaluated based on the following evaluation criteria. Those classified as rank 3 or higher are acceptable. The evaluation results are shown in Table 1.

(Evaluation Criteria)

5: Both of the retention ratio of elongation at break and the retention ratio of breaking stress are 80% or more;

4: Both of the retention ratio of elongation at break and the retention ratio of breaking stress are 70% or more and less than 80%;

3: Both of the retention ratio of elongation at break and the retention ratio of breaking stress are 60% or more and less than 70%;

2: Both of the retention ratio of elongation at break and the retention ratio of breaking stress are 50% or more and less than 60%; and

1: Both of the retention ratio of elongation at break and the retention ratio of breaking stress are less than 50%.

—Evaluation of Adhesion—

The adhesion between the adhesive layer and substrate of the solar cell backsheet 1 was evaluated using an adhesive.

Firstly, two sheets of samples having a length of 120 mm and a width of 50 mm were cut out from the solar cell backsheet 1. The samples cut out from the solar cell backsheet 1 were referred to as test sample (A).

Secondly, a release test film having an adhesive layer was prepared in the same manner as above except that the thickness of the substrate film was 120 μm, and two sheets of samples having a length of 120 mm and a width of 50 mm were cut out therefrom. The samples cut out from the release test film are referred to as test sample (B).

The adhesive layer side of the test sample (A) was coated with an urethane-isocyanate adhesive in a thickness of 5 μm, which was then bonded to the adhesive layer side of the test sample (B). The assembly was allowed to stand at 40° C. for 5 days, cured for adhesion, and thus obtaining a bonded sample.

The bonded sample thus obtained was cut into a 20 mm width piece, and, in *accordance with JIS K6854-2 (1999), the bonded sample piece was held at the test sample (A) side and the test sample (B) side, and drawn to the opposite sides at a rate of 100 mm/minute, thereby carrying out 180° peel test.

The 180° peel test was carried out on the bonded sample before the acceleration test wherein the sample was allowed to stand at 105° C. and 100% RH for 48 hours (acceleration test 2), and the bonded sample after the acceleration test 2.

At that time, the peel force was continuously measured, and the maximum value of the continuously measured values was determined. The test was carried out on three bonded samples, and the maximum values were respectively measured. The average of the measured three maximum values was determined as the adhesion force between the solar cell backsheet 1 and adhesive, and used as the index of the adhesion between the substrate and the adhesive layer in the solar cell backsheet 1. The evaluation results are shown in Table 1.

The evaluation result of the bonded sample before the acceleration test 2 was shown in the column A of the “Adhesion”, and the evaluation result of the bonded sample after the acceleration test 2 is shown in the column B of the “Adhesion”.

—Adhesion Properties—

On the basis of the adhesion force thus determined, the “adhesion” were evaluated based on the following evaluation criteria. Those classified as level 3 to level 5 are practically acceptable.

5; The sample was broken with no peeling at the interface,

4; The peel force was 20 N or more,

3; The peel force was 15 N or more and less than 20 N,

2; The peel force was 10 N or more and less than 15 N, and

1; The peel force was less than 10 N, or peeling occurred during the acceleration test 2.

### Example 2

A PET substrate 2 having a thickness of 125 μm was obtained in the same manner as the production the PET substrate 1 of Example 1, except that the heat setting temperature was changed from 225° C. to 215° C.

Subsequently, a solar cell backsheet 2 of Example 2 was produced in the same manner as the solar cell backsheet 1 of Example 1, except that the PET substrate 2 was used in place of the PET substrate 1.

The solar cell backsheet 2 thus obtained was evaluated for the weather resistance and the adhesion using the same evaluation method and the same evaluation criteria as those for the solar cell backsheet 1. The evaluation results are shown in Table 1.

### Example 3

A solar cell backsheet 3 of Example 3 was produced in the same manner as the production of the solar cell backsheet 1 of Example 1, except that the following first layer coating liquid (2) was used in place of the first layer coating liquid (1).

The solar cell backsheet 3 thus obtained was evaluated for the weather resistance and the adhesion using the same evaluation method and the same evaluation criteria as those for the solar cell backsheet 1. The evaluation results are shown in Table 1.

—Preparation of First Layer Coating Liquid (2)—

| | |
|---|---|
| Polyacryl binder (binder) | 19.1 parts |
| [JULIMER ET-410 (trade name), manufactured | |
| by Toagosei Co., Ltd., solid content 30%] | |
| Carbodiimide compound (carbodiimide | 13.5 parts |
| crosslinking agent) | |
| [CARBODILITE V-02-L2 (trade name), | |
| manufactured by Nisshinbo Chemical Inc., | |
| solid content 20%] | |
| Surfactant A | 15.0 parts |
| [1% aqueous solution of NAROACTY CL-95 | |
| (trade name), manufactured by | |
| Sanyo Chemical Industries, Ltd.] | |
| Inorganic filler (inorganic fine particles) | 73.0 parts |
| [TDL-1 (trade name), manufactured by | |
| Mitsubishi Materials Electronic Chemicals | |
| Co., Ltd., 17% aqueous solution of tin oxide] | |
| Distilled water | An amount to make the |
| | total amount 1,000 parts |

The above-described ingredients were mixed, thereby preparing the first layer coating liquid (2) for forming the first layer.

### Example 4

A solar cell backsheet 4 of Example 4 was produced in the same manner as the production of the solar cell backsheet 1 of Example 1, except that the following first layer coating liquid (3) was used in place of the first layer coating liquid (1).

The solar cell backsheet 4 thus obtained was evaluated for the weather resistance and the adhesion using the same evaluation method and the same evaluation criteria as those for the solar cell backsheet 1. The evaluation results are shown in Table 1.

—Preparation of First Layer Coating Liquid (3)—

| | |
|---|---|
| Polyacryl binder (binder) | 19.1 parts |
| [JULIMER ET-410 (trade name), manufactured | |
| by Toagosei Co., Ltd., solid content 30%] | |
| Carbodiimide compound (carbodiimide | 9.0 parts |
| crosslinking agent) | |
| [CARBODILITE V-02-L2 (trade name), | |
| manufactured by Nisshinbo Chemical Inc., | |
| solid content 20%] | |
| Surfactant A | 15.0 parts |
| [1% aqueous solution of NAROACTY CL-95 | |
| (trade name), manufactured by Sanyo | |
| Chemical Industries, Ltd.] | |
| Inorganic filler (inorganic fine particles) | 109.5 parts |
| [TDL-1 (trade name), manufactured by | |
| Mitsubishi Materials Electronic Chemicals | |
| Co., Ltd., 17% aqueous solution of tin oxide] | |
| Distilled water | An amount to make the |
| | total amount 1,000 parts |

The above-described ingredients were mixed, whereby preparing the first layer coating liquid (3) for forming the first layer.

### Comparative Example 1

A PET substrate 101 having a thickness of 125 μm was obtained in the same manner as the production of the PET substrate 1 of Example 1, except that the heat setting temperature was changed from 225° C. to 150° C.

Subsequently, a solar cell backsheet 101 of Comparative Example 1 was produced in the same manner as the solar cell backsheet 1 of Example 1, except that the PET substrate 101 was used in place of the PET substrate 1.

The solar cell backsheet 101 thus obtained was evaluated for the weather resistance and the adhesion using the same evaluation method and the same evaluation criteria as those for the solar cell backsheet 1. The evaluation results are shown in Table 1.

—Preparation of First Layer Coating Liquid (101)—

| | |
|---|---|
| Polyacryl binder (binder) | 19.1 parts |
| [JULIMER ET-410 (trade name), manufactured | |
| by Toagosei Co., Ltd., solid content 30%] | |
| Oxazoline compound (oxazoline crosslinking agent) | 4.5 parts |
| [EPOCROS WS-700(trade name), manufactured | |
| by Nippon Shokubai Co., Ltd., solid content 25%] | |
| Surfactant A | 15.0 parts |
| [1% aqueous solution of NAROACTY CL-95 | |
| (trade name), manufactured by | |
| Sanyo Chemical Industries, Ltd.] | |
| Inorganic filler (inorganic fine particles) | 36.5 parts |
| [TDL-1 (trade name), manufactured by | |
| Mitsubishi Materials Electronic Chemicals | |
| Co., Ltd., 17% aqueous solution of tin oxide] | |
| Distilled water | An amount to make the |
| | total amount 1,000 parts |

The above-described ingredients were mixed, thereby preparing the first layer coating liquid (101) for forming the first layer.

### Comparative Example 2

A solar cell backsheet 102 of Comparative Example 2 was produced in the same manner as the production of the solar cell backsheet 101 of Comparative Example 1, except that the PET substrate 1 was used in place of the PET substrate 101.

The solar cell backsheet 102 thus obtained was evaluated for the weather resistance and the adhesion using the same evaluation method and the same evaluation criteria as those for the solar cell backsheet 1. The evaluation results are shown in Table 1.

### Comparative Example 3

A solar cell backsheet 103 of Comparative Example 3 was produced in the same manner as the production of the solar cell backsheet 102 of Comparative Example 2, except that the following first layer coating liquid (102) was used in place of the first layer coating liquid (101). The first layer coating liquid (102) was prepared referring to the preparation of the white layer-forming aqueous composition 1 in JP-A No. 2011-146659.

The solar cell backsheet 103 thus obtained was evaluated for the weather resistance and the adhesion using the same evaluation method and the same evaluation criteria as those for the solar cell backsheet 1. The evaluation results are shown in Table 1.

—Preparation of the First Layer Coating Liquid (102)—

| | |
|---|---|
| Polyacryl binder (binder) | 7.2 parts |
| [JULIMER ET-410 (trade name), manufactured | |
| by Toagosei Co., Ltd., solid content 30%] | |
| Oxazoline compound (oxazoline crosslinking agent) | 2.0 parts |
| [EPOCROS WS-700(trade name), manufactured | |
| by Nippon Shokubai Co., Ltd., solid content 25%] | |
| Surfactant A | 3.0 parts |
| [1% aqueous solution of NAROACTY CL-95 (trade | |
| name), manufactured by Sanyo Chemical Industries, Ltd.] | |
| Silica filler (inorganic fine particles, volume | 1.8 parts |
| average particle size 40 nm) | |
| [AEROSIL OX-50 (trade name), manufactured | |
| by Nippon Aerosil Co., Ltd., solid content 10%] | |
| White pigment dispersion 1 described below | 71.0 parts |
| Distilled water | 15.0 parts |

The above-described ingredients were mixed, thereby preparing the first layer coating liquid (102) for forming the first layer. The white pigment dispersion 1 was prepared as follows.

—Preparation of White Pigment Dispersion 1—

| | |
|---|---|
| Titanium dioxide (white pigment, volume average | 39.7 parts |
| particle diameter of 0.3 μm) | |
| [TIPAQUE R-780-2 (trade name), manufactured | |
| by Ishihara Sangyo Kaisha, Ltd., solid content 100%] | |
| Polyvinyl alcohol (aqueous binder B) | 49.7 parts |
| [PVA-105 (trade name), manufactured by | |
| Kuraray Co., Ltd., solid content 10%] | |
| Surfactant | 0.5 parts |
| [DEMOL EP (trade name), manufactured by | |
| Kao Corporation, solid content 25%] | |
| Distilled water | 10.1 parts |

The titanium dioxide, the aqueous binder B, and the surfactant of the above-described ingredients were mixed with distilled water to make the total 100%, and the mixture was dispersed using a dynomill disperser, thereby obtaining a white pigment dispersion 1.

<Measurement of Pre-Peak Temperature of PET Substrate>

The PET substrates 1, 2, and 101 used in Examples 1 to 4 and Comparative Examples 1 to 3 were subjected to differential scanning calorimetry (DSC) using a differential scanning calorimeter [DSC-50 (trade name), manufactured by Shimadzu Co., Ltd.], to measure the pre-peak temperature of the PET substrates. The measurement results are shown in Table 1.

<Relationship Between Mass Ratio X of Acrylic Resin and Carbodiimide Crosslinking Agent in First Layer (Coating Layer), Acid Value A of Acrylic Resin, and Carbodiimide Equivalent B>

The mass ratio X of the acrylic resin and carbodiimide crosslinking agent in the first layer used to produce the solar cell backsheets 1 to 4 (“the mass of the carbodiimide crosslinking agent in the first layer”/“the mass of the acrylic resin in the first layer”), the acid value A of the acrylic resin, and the carbodiimide equivalent B are listed in Table 1.

TABLE 1

| | Substrate | | | | | | | | | | Second layer | | | | |
|---|---|---|---|---|---|---|---|---|---|---|---|---|---|---|---|
| | | Heat | | First layer (coating layer) | | | | | | | (adhesive ayer) | | | | |
| | | setting | Prepeak | Mass | Binder | Crosslinking agent | | | | | Crosslinking | | Evaluation | | |
| | | temper- | temper- | ratio | Acid | Equiva- | | | Fine particles | | agent | Binder | Weather | Adhe- | |
| | Type | ature | ature | X | value A | lent B | Type | Amount | Type | Amount | Type | Type | resis- | sion | |
| | — | ° C. | ° C. | — | mgKOH/g | g/mol | — | % | % | — | — | — | tance | A | B |
| Ex 1 | PET | 225 | 214 | 0.314 | 50 | 384 | Carbodiimide | 9 | Tin | 62 | Epoxy | Acryl | 3 | 4 | 3 |
| | | | | | | | | | oxide | | | | | | |
| Ex 2 | PET | 215 | 205 | 0.314 | 50 | 384 | Carbodiimide | 9 | Tin | 62 | Epoxy | Acryl | 4 | 3 | 3 |
| | | | | | | | | | oxide | | | | | | |
| Ex 3 | PET | 225 | 214 | 0.471 | 50 | 384 | Carbodiimide | 13.5 | Tin | 62 | Epoxy | Acryl | 3 | 5 | 4 |
| | | | | | | | | | oxide | | | | | | |
| Ex 4 | PET | 225 | 214 | 0.314 | 50 | 384 | Carbodiimide | 9 | Tin | 74.4 | Epoxy | Acryl | 3 | 5 | 4 |
| | | | | | | | | | oxide | | | | | | |
| C Ex 1 | PET | 150 | 144 | — | — | | Oxazoline | 4.5 | Tin | 62 | Epoxy | Acryl | 4 | 1 | 1 |
| | | | | | | | | | oxide | | | | | | |
| C Ex 2 | PET | 225 | 214 | — | — | | Oxazoline | 4.5 | Tin | 62 | Epoxy | Acryl | 3 | 2 | 2 |
| | | | | | | | | | oxide | | | | | | |
| C Ex 3 | PET | 225 | 214 | — | — | | Oxazoline | 4.5 | Silica | 62 | Epoxy | Acryl | 3 | 2 | 1 |

Ex: Example
C Ex: Compartive Example

As shown in Table 1, the solar cell backsheet 101 of Comparative Example 1 showed insufficient weather resistance, although their evaluation results of the adhesion were within the acceptable range. On the other hand, the solar cell backsheets 1 to 4 of Examples 1 to 4 showed high weather resistance and high adhesion.

### Examples 5 to 8

A tempered glass sheet having a thickness of 3 mm, an EVA sheet (SC50B (trade name), manufactured by Mitsui Chemicals Fabro, Inc.), a crystalline solar cell, an EVA sheet (SC50B (trade name), manufactured by Mitsui Chemicals Fabro, Inc.), and the solar cell backsheet produced in any of Examples 1 to 4 are disposed one another in layers in this order, which were then subjected to hot-pressing for adhesion with the EVA using a vacuum laminator (vacuum laminator manufactured by Nisshinbo Chemical Inc.), thereby producing a crystalline solar cell modules 1 to 4. At that time, the solar cell backsheet was arranged in such a manner that the adhesive layer is in contact with the EVA sheet, and the adhesion was carried out by the method described below.

—Bonding Method—

The assembly was subjected to vacuum at 128° C. for 3 minutes using a vacuum laminator, and then pressure is applied thereto for 2 minutes for temporal adhesion. Thereafter, main adhesion treatment was carried out in a dry oven at 150° C. for 30 minutes.

The solar cell modules 1 to 4 produced as described above were used for electric generating operation, and found to have favorable electric-generating performance as a solar cell.

Disclosure of Japan application No. 2011-200955 is incorporated herein by reference.

All the references, patent applications, and technical specifications are incorporated herein by reference to the same extent that incorporation of individual references, patent applications, and technical specifications by reference is specifically and individually described.

1. A solar cell backsheet comprising:
a substrate that is a biaxially stretched polyethylene terephthalate film having a pre-peak temperature of from 160° C. to 225° C. as measured by differential scanning calorimetry (DSC):
a coating layer that is provided at at least one side of the substrate, and comprises a binder containing an acrylic resin, a crosslinked structure part derived from a carbodiimide crosslinking agent, and inorganic fine particles; and
an adhesive layer that is provided on the coating layer, and comprises a resin binder as a main component.

2. The solar cell backsheet according to claim 1, wherein an acid value A of the acrylic resin, an equivalent B of the carbodiimide crosslinking agent, and a mass ratio X of the carbodiimide crosslinking agent to the acrylic resin (carbodiimide crosslinking agent/acrylic resin) satisfies the following Formula (1):
(0.8AB)/56100<X<(2.0AB)/56100 (1).

3. The solar cell backsheet according to claim 1, wherein the inorganic fine particles contain tin oxide.

4. The solar cell backsheet according to claim 1, wherein the inorganic fine particles contain tin oxide as a main component, and a content of the inorganic fine particles in the coating layer is from 50% by mass to 500% by mass with respect to a total mass of the binder.

5. The solar cell backsheet according to claim 1, wherein the pre-peak temperature of the substrate is from 205° C. to 225° C.

6. The solar cell backsheet according to claim 1, wherein a content of the binder in the coating layer is from 0.02 g/m² to 0.1 g/m².

7. The solar cell backsheet according to claim 1, wherein an equivalent B of the carbodiimide crosslinking agent is from 200 to 500.

8. The solar cell backsheet according to claim 1, wherein the adhesive layer further comprises a crosslinked structure part derived from an epoxy crosslinking agent.

9. A solar cell module comprising:
a transparent substrate into which sunlight enters,
a solar cell element disposed at one side of the substrate, and
the solar cell backsheet according to claim 1 disposed at an opposite side of the solar cell element from a side of the solar cell element at which the substrate is disposed.

10. The solar cell backsheet according to claim 2, wherein the inorganic fine particles contain tin oxide.

11. The solar cell backsheet according to claim 2, wherein the inorganic fine particles contain tin oxide as a main component, and a content of the inorganic fine particles in the coating layer is from 50% by mass to 500% by mass with respect to a total mass of the binder.

12. The solar cell backsheet according to claim 2, wherein the pre-peak temperature of the substrate is from 205° C. to 225° C.

13. The solar cell backsheet according to claim 2, wherein a content of the binder in the coating layer is from 0.02 g/m² to 0.1 g/m².

14. The solar cell backsheet according to claim 2, wherein an equivalent B of the carbodiimide crosslinking agent is from 200 to 500.

15. The solar cell backsheet according to claim 2, wherein the adhesive layer further comprises a crosslinked structure part derived from an epoxy crosslinking agent.

16. A solar cell module comprising:
a transparent substrate into which sunlight enters,
a solar cell element disposed at one side of the substrate, and
the solar cell backsheet according to any one of claim 2 disposed at an opposite side of the solar cell element from a side of the solar cell element at which the substrate is disposed.
